(19) United States
(12) Patent Application Publication
(10) Pub. No.: US 2025/0338551 A1
(43) Pub. Date: Oct. 30, 2025

(54) TFT WITH HYDROGEN ABSORPTION LAYER AND METHOD FOR FORMING THE SAME

(71) Applicant: Taiwan Semiconductor Manufacturing Company, Ltd., Hsinchu (TW)

(72) Inventors: Yen-Chung Ho, Hsinchu (TW); Katherine H. Chiang, New Taipei City (TW); Hui-Hsien Wei, Taoyuan City (TW); Tsu Ching Yang, Taipei (TW); Hsin-Yu Lai, Hsinchu (TW); Kuo-Chang Chiang, Hsinchu City (TW); Yong-Jie Wu, Tainan City (TW)

(21) Appl. No.: 19/264,924

(22) Filed: Jul. 10, 2025

Related U.S. Application Data
(63) Continuation of application No. 18/618,063, filed on Mar. 27, 2024.
(60) Provisional application No. 63/610,443, filed on Dec. 15, 2023.

(51) Int. Cl. H10D 30/67; H10D 99/00

(52) U.S. Cl. CPC H10D 30/6704; H10D 30/6755; H10D 99/00

(57) ABSTRACT

Various embodiments of the present disclosure are directed to a thin-film transistor (TFT) with a hydrogen absorption layer and a method for forming the same. The TFT comprises a semiconductor channel, a gate electrode, and a gate dielectric layer that are stacked with the gate dielectric layer separating the gate electrode from the semiconductor channel. A first source/drain electrode and a second source/drain electrode are respectively on different portions of the semiconductor channel. Further, the hydrogen absorption layer is adjacent to the gate electrode, the first source/drain electrode, the second source/drain electrode, or a combination thereof. The hydrogen absorption layer traps hydrogen and other errant particles from interacting with semiconductor material of the TFT to prevent performance and reliability degradation.

### REFERENCE TO RELATED APPLICATIONS

This application is a Continuation of U.S. application Ser. No. 18/618,063, filed on Mar. 27, 2024, which claims the benefit of U.S. Provisional Application No. 63/610,443, filed on Dec. 15, 2023. The contents of the above-referenced patent applications are hereby incorporated by reference in their entirety.

### BACKGROUND

A thin-film transistor (TFT) is a type of field-effect transistor (FET) in which a semiconductor channel of the TFT is formed by thin film deposition onto a non-conducting substrate. One type of TFT is an oxide-semiconductor TFT. An oxide-semiconductor TFT is compatible with back-end-of-line (BEOL) processing and hence is a promising candidate for next generation memory applications and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a thin-film transistor (TFT) comprising a hydrogen absorption layer.

FIG. 2 illustrates a top layout view of some embodiments of the TFT of FIG. 1.

FIG. 3 illustrates a cross-sectional view of some embodiments of an integrated circuit (IC) comprising a plurality of TFTs as in FIG. 1.

FIG. 4 illustrates a cross-sectional view of some alternative embodiments of the TFT of FIG. 1 in which the conductive barrier is omitted.

FIGS. 5A-5C illustrate cross-sectional views of some alternative embodiments of the TFT of FIG. 4.

FIG. 6 illustrates a cross-sectional view of some alternative embodiments of the TFT of FIG. 1 in which a plurality of hydrogen absorption layers and a plurality of conductive layers are alternatingly stacked to form a gate electrode of the TFT.

FIG. 7 illustrates a cross-sectional view of some alternative embodiments of the TFT of FIG. 1 in which a gate electrode of the TFT overlies a semiconductor channel of the TFT.

FIGS. 8A and 8B illustrate cross-sectional views of some alternative embodiments of the TFT of FIG. 7.

FIG. 9 illustrates a cross-sectional view of some alternative embodiments of the TFT of FIG. 1 in which the TFT comprises additional hydrogen absorption layers respectively at source/drain electrodes of the TFT.

FIGS. 10A-10C illustrate cross-sectional views of some alternative embodiments of the TFT of FIG. 9.

FIGS. 11-22 illustrate a series of cross-sectional views of some embodiments of a method for forming a TFT with a hydrogen absorption layer.

FIG. 23 illustrates a block diagram of some embodiments of the method of FIGS. 11-22.

FIGS. 24-27 illustrate a series of cross-sectional views of some first alternative embodiments of the method of FIGS. 11-22.

FIGS. 28-30 illustrate a series of cross-sectional views of some second alternative embodiments of the method of FIGS. 11-22.

FIGS. 31-33 illustrate a series of cross-sectional views of some third alternative embodiments of the method of FIGS. 11-22.

FIGS. 34-36 illustrate a series of cross-sectional views of some fourth alternative embodiments of the method of FIGS. 11-22.

FIGS. 37-42 illustrate a series of cross-sectional views of some fifth alternative embodiments of the method of FIGS. 11-22.

FIGS. 43 and 44 illustrate a series of cross-sectional views of some sixth alternative embodiments of the method of FIGS. 11-22.

FIGS. 45-48 illustrate a series of cross-sectional views of some embodiments of a method for forming an IC comprising a TFT with a hydrogen absorption layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An oxide-semiconductor thin-film transistor (TFT) may be formed in a back-end-of-line (BEOL) interconnect structure, whereby the oxide-semiconductor TFT may be exposed to hydrogen. For example, hydrogen from BEOL layers formed before formation of the oxide-semiconductor TFT may migrate to the oxide-semiconductor TFT. Such BEOL layers may include high-k dielectric layers, interlayer dielectric (TLD) layers, and so on. As another example, hydrogen from BEOL processing performed after formation of the oxide-semiconductor TFT may migrate to the oxide-semiconductor TFT.

Oxide-semiconductor material of the oxide-semiconductor TFT may be sensitive to hydrogen, whereby hydrogen exposure may degrade performance and reliability of the oxide-semiconductor TFT. For example, ON current (I_{ON}) of the oxide-semiconductor TFT may be decreased and/or threshold-voltage variation while the oxide-semiconductor TFT is under stress (e.g., thermal stress or the like) may be increased. Because forming the oxide-semiconductor TFT in a BEOL interconnect structure may lead to hydrogen exposure, performance and reliability of the oxide-semiconductor TFT may be degraded. Further, this degradation may become increasingly severe as the oxide-semiconductor TFT is scaled down.

Various embodiments of the present disclosure are directed to an oxide-semiconductor TFT with a hydrogen absorption layer and a method for forming the same. The hydrogen absorption layer traps hydrogen and other errant particles from interacting with oxide-semiconductor material of the oxide-semiconductor TFT. This, in turn, prevents performance and reliability degradation of the oxide-semiconductor TFT.

In some embodiments, the oxide-semiconductor TFT comprises a semiconductor channel, a gate electrode, and a gate dielectric layer that are stacked with the gate dielectric layer between the gate electrode and the semiconductor channel. A first source/drain electrode and a second source/drain electrode are respectively on different portions of the semiconductor channel. Further, the hydrogen absorption layer is adjacent to the gate electrode, the first source/drain electrode, the second source/drain electrode, or a combination thereof.

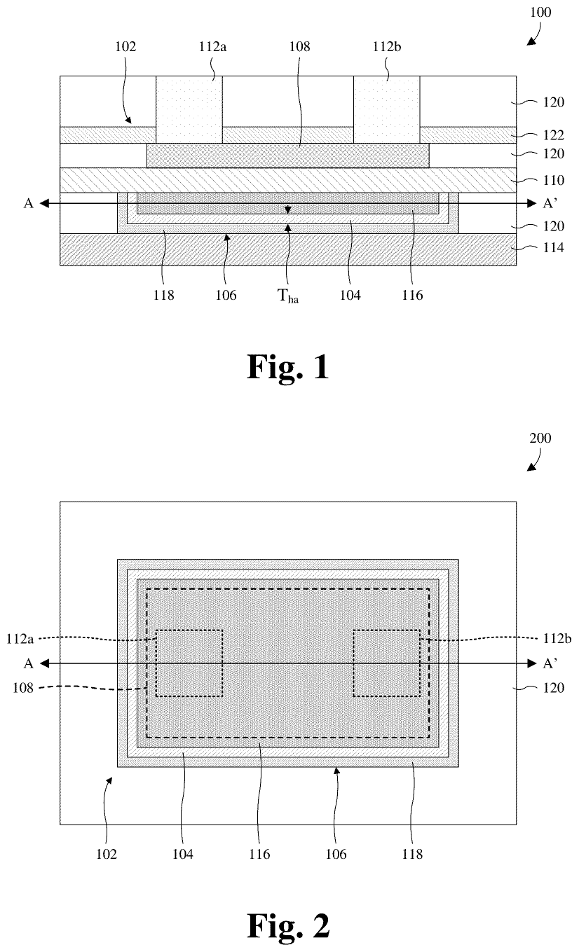

With reference to FIG. 1, a cross-sectional view 100 of some embodiments of a TFT 102 comprising a hydrogen absorption layer 104 is provided. The TFT 102 may, for example, be an oxide-semiconductor TFT or some other suitable type of TFT. Further, as seen hereafter, the TFT 102 may, for example, be formed in a BEOL interconnect structure.

The hydrogen absorption layer 104 is embedded in a gate electrode 106, which underlies and is spaced from a semiconductor channel 108 by a gate dielectric layer 110. Further, a first source/drain electrode 112a and a second source/drain electrode 112b overlie the semiconductor channel 108 and are electrically coupled respectively to opposite ends of the semiconductor channel 108. Source/drain electrode(s) may refer to a source electrode or a drain electrode, individually or collectively dependent upon the context.

The semiconductor channel 108 is sensitive to hydrogen, which the hydrogen absorption layer 104 has a propensity to absorb. Such sensitivity may lead to performance and/or reliability degradation of the TFT 102 in response to exposure of the semiconductor channel 108 to hydrogen. For example, exposure may decrease ON current (e.g., I_{ON}) of the TFT 102. As another example, exposure may increase threshold-voltage variation while the TFT 102 is under thermal stress and/or some other suitable type of stress.

In some embodiments, when the TFT 102 is formed in a BEOL interconnect structure, hydrogen may migrate towards the semiconductor channel 108. For example, hydrogen from BEOL layers formed before formation of the TFT 102 may migrate towards the semiconductor channel 108. As another example, hydrogen from BEOL processing performed after formation of the TFT 102 may migrate towards the semiconductor channel 108.

Because the hydrogen absorption layer 104 is embedded in the gate electrode 106, the hydrogen absorption layer 104 is proximate to the semiconductor channel 108. This proximity, together with a propensity to absorb hydrogen, allows the hydrogen absorption layer 104 to absorb and prevent hydrogen from migrating to and interacting with the semiconductor channel 108. This may, in turn, enhance performance (e.g., increase ON current) of the TFT 102 and enhance reliability (e.g., decrease threshold-voltage variation) of the TFT 102.

In some embodiments, the hydrogen absorption layer 104 is a material that couples with hydrogen at room temperature and/or at operating temperatures of the TFT 102. Further, in some embodiments, the hydrogen absorption layer 104 is or comprises a noble metal, indium gallium zinc oxide (e.g., InGaZnO), an n-type metal oxide, or other suitable materials with a propensity to absorb hydrogen. The noble metal may, for example, have a nanocrystalline structure that facilitates absorption and trapping of hydrogen. The noble metal may, for example, be or comprise platinum (e.g., Pt), silver (e.g., Ag), palladium (e.g., Pd), gold (e.g., Au), the like, or any combination of the foregoing.

In some embodiments, the n-type metal oxide is or comprise an indium-oxide based semiconductor that is doped with n-type dopants. The indium-oxide based semiconductor may, for example, be or comprise InₓM_{y}O, wherein M is an element and x and y are numerical values. In some embodiments, the element is tungsten (e.g., W), titanium (e.g., Ti), gallium (e.g., Ga), zinc (e.g., Zn), calcium (e.g., Ca), magnesium (e.g., Mg), tin (e.g., Sn), a rare-earth element, or the like. In some embodiments, a ratio of x to y (e.g., x/y) is greater than zero and less than 1. Other suitable values are, however, amenable for the ratio.

In some embodiments, the n-type metal oxide (e.g., the indium-oxide based semiconductor described above) is doped with n-type dopants to a high carrier concentration greater than 1E19 atoms per cubic centimeter (e.g., atoms/cm³) so as not to materially increase resistance of the gate electrode 106. Further, in some embodiments, the n-type metal oxide has a carrier concentration that is about 1E19 atoms/cm³ to 1E21 atoms/cm³. Other suitable carrier concentrations are, however, amenable in alternative embodiments.

In some embodiments, a thickness Tₕₐ of the hydrogen absorption layer 104 is about 5-20 nanometers, about 5-10 nanometers, about 10-15 nanometers, about 15-20 nanometers, or some other suitable value or range of values. In some embodiments in which the hydrogen absorption layer 104 is or comprises the n-type metal oxide, the thickness Tₕₐ of the hydrogen absorption layer 104 is about 0.5-10 nanometers, about 0.5-5 nanometers, about 5-10 nanometers, or some other suitable value or range of values. If the thickness Tₕₐ is too large (e.g., greater than 10 nanometers), a resistance of the gate electrode 106 may be materially degraded, thereby degrading performance of the TFT 102. If the thickness Tₕₐ is too small (e.g., less than 0.5 nanometers), the hydrogen absorption layer 104 may be ineffective at absorbing and preventing hydrogen from migrating to and interacting with the semiconductor channel 108.

In some embodiments, the hydrogen absorption layer 104 comprises hydrogen absorbed from BEOL layers and/or BEOL processing. Further, in some embodiments, the hydrogen absorption layer 104 has a concentration of hydrogen greater than a concentration of hydrogen in the semiconductor channel 108. The concentration of hydrogen in the hydrogen absorption layer 104 may, for example, be greater than about 1E15 atoms/cm³, 1E19 atoms/cm³, or some other suitable value. In some embodiments, the semiconductor channel 108 is devoid or substantially devoid of hydrogen. For example, the semiconductor channel 108 may have a concentration of hydrogen less than about 1E15 atoms/cm³, 1E10 atoms/cm³, or some other suitable value.

In some embodiments, the semiconductor channel 108 is or comprises indium zinc oxide (e.g., IZO), indium tin oxide (e.g., ITO), indium oxide (e.g., In₂O₃), gallium oxide (e.g., Ga₂O₃), indium gallium zinc oxide (e.g., InGaZnO), zinc oxide (e.g., ZnO), aluminum zinc oxide (e.g., Al₂O₅Zn₂), aluminum-doped zinc oxide (e.g., AZO), indium tungsten oxide (e.g., IWO), titanium oxide (e.g., TiOx), the like, or any combination of the foregoing. In some embodiments, the semiconductor channel 108 may also be regarded as a semiconductor body.

With continued reference to FIG. 1, the gate electrode 106 overlies a dielectric substrate 114, which may also be regarded as a dielectric layer or the like. The gate electrode 106 comprises a conductive body 116 and a conductive liner 118. The conductive liner 118 extends along a bottom surface of the conductive body 116 and sidewalls of the conductive body 116. Further, the conductive liner 118 is separated from the conductive body 116 by the hydrogen absorption layer 104. In some embodiments, the conductive liner 118 serves as a diffusion barrier for material of the conductive body 116, thereby preventing outward diffusion. Hence, in such embodiments, the conductive liner 118 may also be known as a barrier layer.

During use of the TFT 102, the semiconductor channel 108 selectively conducts from the first source/drain electrode 112a to the second source/drain electrode 112b depending on a bias voltage applied to at the gate electrode 106. For example, the semiconductor channel 108 may conduct when the bias voltage is more than a threshold voltage and may not conduct when the bias voltage is less than the threshold voltage, or vice versa.

In some embodiments, the conductive body 116 is or comprise metal. For example, the conductive body 116 may be or comprise copper, aluminum copper, tungsten, some other suitable metal or metal-containing material, or any combination of the foregoing. The conductive liner 118 is or comprises titanium nitride, tantalum nitride, some other suitable barrier material for the conductive body 116, or any combination of the foregoing.

In some embodiments, in which the hydrogen absorption layer 104 is or comprises the n-type metal oxide and the conductive body 116 is or comprises metal, the hydrogen absorption layer 104 forms a heterojunction with the conductive body 116. Further, an energy gap and shallow trap states form at the heterojunction. The energy gap corresponds to an energy difference between a fermi level of the conductive body 116 and the band gap of the hydrogen absorption layer 104. In some embodiments, the band gap is recessed relative to the fermi level so there is a step down in energy from the fermi level to the band gap. The shallow trap states are in the band gap and serve as a reservoir to trap and store hydrogen.

In some embodiments, the energy gap forms because of an energy difference between a fermi level of the conductive body 116 and a conduction band edge of the n-type metal oxide. The fermi level of the conductive body 116 may, for example, be be demarcated by a work function of the conductive body 116, which may, for example, be about 4-5 electron volts (eV), about 4-4.5 eV, about 4.5-5 eV, or some other suitable values. The conductive band edge of the n-type metal oxide may, for example, be less than the fermi level of the conductive body 116 and may, for example, be at about 0.2-3 eV, about 0.2-1.6 eV, about 1.6-3 eV, or some other suitable values. In other embodiments, the energy gap forms because of fermi-level pinning from an energy difference between a conduction band edge of the n-type metal oxide and a valence band edge of the n-type metal oxide. Further, in some embodiments, the band gap of the n-type metal oxide may be about 1-3 eV or some other suitable value or range of energy values.

In some embodiments, in which the hydrogen absorption layer 104 is or comprises the n-type metal oxide described above and the conductive liner 118 is or comprises metal, the hydrogen absorption layer 104 forms a heterojunction with the conductive liner 118. Further, an energy gap forms in the hydrogen absorption layer 104 at the heterojunction and forms such that it traps hydrogen and serves as a reservoir for the trapped hydrogen.

A plurality of dielectrics layers 120 and a hydrogen blocking layer 122 are stacked over the dielectric substrate 114 and surround the TFT 102. A lower one of the dielectric layers 120 surrounds the gate electrode 106, between the dielectric substrate 114 and the gate dielectric layer 110. A middle one of the dielectric layers 120 surrounds the semiconductor channel 108, between the gate dielectric layer 110 and the hydrogen blocking layer 122. In some embodiments, the gate dielectric layer 110 is or comprises a high k dielectric material and/or some other suitable dielectric material(s), and/or the dielectric layers 120 are or comprise a low k dielectric material and/or some other suitable dielectric material(s).

The hydrogen blocking layer 122 and an upper one of the dielectric layers 120 overlie the semiconductor channel 108 and the middle one of the dielectric layers 120. Further, the hydrogen blocking layer 122 and the upper one of the dielectric layers 120 surround the first and second source/drain electrodes 112a, 112b. The hydrogen blocking layer 122 serves to block hydrogen from migrating to the semiconductor channel 108, which may further prevent performance and/or reliability degradation of the TFT 102.

In some embodiments, the hydrogen blocking layer 122 does not couple with and/or absorb hydrogen to trap the hydrogen. This is to be contrasted with the hydrogen absorption layer 104. As such, even if the hydrogen blocking layer 122 initially blocks hydrogen, the hydrogen may still migrate around the hydrogen blocking layer 122. For example, hydrogen may migrate around the hydrogen blocking layer 122 along a sidewall interface between the first source/drain electrode 112a and the hydrogen blocking layer 122.

While the hydrogen absorption layer 104 is described as absorbing hydrogen, the hydrogen absorption layer 104 may additionally or alternatively absorb other errant particles detrimental to the TFT 102. Hence, in some embodiments, the hydrogen absorption layer 104 may also be referred to as an absorption layer, an errant-particle absorption layer, or the like. Similarly, while the hydrogen blocking layer 122 is described as blocking hydrogen, the hydrogen blocking layer 122 may additionally or alternatively block other errant particles detrimental to the TFT 102. Hence, in some embodiments, the hydrogen blocking layer 122 may also be referred to as a blocking layer, an errant-particle blocking layer, or the like.

With reference to FIG. 2, a top layout view 200 of some embodiments of the TFT 102 of FIG. 1. The cross-sectional view 100 of FIG. 1 may, for example, be taken along line A-A′ in FIG. 2, and/or the top layout view 200 may, for example, be taken along line A-A′ in FIG. 1. Further, the semiconductor channel 108, the first source/drain electrode 112a, and the second source/drain electrode 112b are shown in phantom.

The conductive liner 118 extends in a closed path along sidewalls of the hydrogen absorption layer 104 to surround the hydrogen absorption layer 104. The hydrogen absorption layer 104 separates the conductive liner 118 from the conductive body 116. Further, the hydrogen absorption layer 104 extends in a closed path along sidewalls of the conductive body 116 to surround the conductive body 116. The semiconductor channel 108 overlaps with the conductive body 116 and is confined to an area of the conductive body 116. Similarly, the first and second source/drain electrodes 112a, 112b overlap with the semiconductor channel 108. Further, the first and second source/drain electrodes 112a, 112b are confined to an area of the semiconductor channel 108 and area respectively on opposite ends of the semiconductor channel 108.

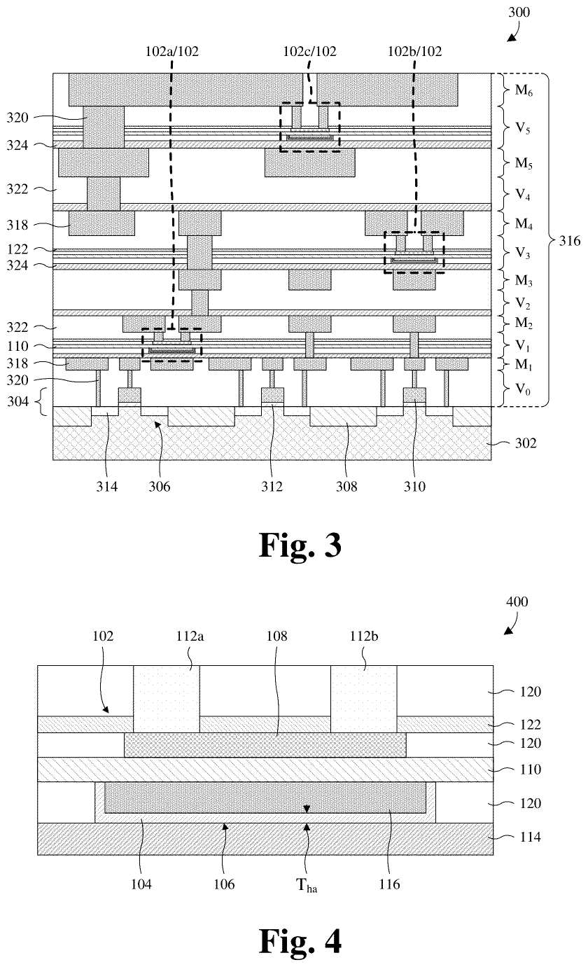

With reference to FIG. 3, a cross-sectional view 300 of some embodiments of an integrated circuit (IC) comprising a plurality of TFTs 102, each as in FIG. 1, is provided. The plurality of TFTs 102 overlie a semiconductor substrate 302 and comprise a first TFT 102a, a second TFT 102b, and a third TFT 102c respectively at different elevations above the semiconductor substrate 302. In alternative embodiments, any one or two of plurality of TFTs 102 may be omitted and/or any one or more of the plurality of TFTs 102 may be at different elevation(s). In some embodiments, the semiconductor substrate 302 is or comprises silicon, germanium, some other suitable material, or any combination of the foregoing.

A device layer 304 overlies the semiconductor substrate 302, between the semiconductor substrate 302 and the plurality of TFTs 102. Further, the device layer 304 includes a plurality of logic devices 306. In some embodiments, the device layer 304 includes additional device types and/or may also be referred to as a front-end-of-line (FEOL) layer.

The plurality of logic devices 306 are partially formed by the semiconductor substrate 302 and are separated from each other by an isolation structure 308. The isolation structure 308 may, for example, be or comprise a shallow trench isolation (STI) structure, a deep trench isolation (DTI) structure, a local oxidation of silicon (LOCOS) isolation structure, some other suitable isolation structure, or any combination of the foregoing. Further, the plurality of logic devices 306 may, for example, be planar field-effect transistors (planar FETs), fin field-effect transistors (FinFETs), gate-all-around (GAA) field-effect transistors (GAA FETs), some other suitable type of logic device and/or transistor, or any combination of the foregoing.

The plurality of logic devices 306 comprise individual gate electrodes 310, individual gate dielectric layers 312, and individual pairs of source/drain regions 314. Source/drain region(s) may refer to a source region or a drain region, individually or collectively dependent upon the context. The pairs of source/drain regions 314 are inset into a top of the semiconductor substrate 302. The gate electrodes 310 respectively overlie the gate dielectric layers 312 and are respectively between the pairs of source/drain regions 314.

A BEOL interconnect structure 316 overlies and is electrically coupled to devices of the device layer 304 (e.g., the plurality of logic devices 306). Further, the BEOL interconnect structure 316 surrounds and electrically couples to the plurality of TFTs 102. The BEOL interconnect structure 316 comprises a plurality of wires 318 and a plurality of vias 320. The plurality of wires 318 are grouped into a plurality of wire levels, and the plurality of vias 320 are grouped into a plurality of via levels. Further, the plurality of wire levels and the plurality of vias levels are alternatingly stacked vertically from a bottom of the BEOL interconnect structure 316 to a top of the BEOL interconnect structure 316.

The plurality of wire levels are labeled M₁, M₂, and so on to M₆ from the bottom of the BEOL interconnect structure 316 to the top of the BEOL interconnect structure 316. Similarly, the plurality of via levels are labeled V₀, V₁, and so on to V₅ from the bottom of the BEOL interconnect structure 316 to the top of the BEOL interconnect structure 316. In some embodiments, the plurality of wire levels increase in height from the bottom of the BEOL interconnect structure 316 to the top of the BEOL interconnect structure 316. In some embodiments, the plurality of via levels increase in height and/or width from the bottom of the BEOL interconnect structure 316 to the top of the BEOL interconnect structure 316.

The first TFT 102a is between wire level M₁ and wire level M₂ but may be between any other two neighboring wire levels in other embodiments. The second TFT 102b is between wire level M₃ and wire level M₄ but may be between any other two neighboring wire levels in other embodiments. The third TFT 102c is between wire level M₅ and wire level M₆ but may be between any other two neighboring wire levels in other embodiments.

A dielectric stack surrounds the BEOL interconnect structure 316 and comprises a plurality of interconnect dielectric layers 322 and a plurality of etch stop layers 324. The plurality of interconnect dielectric layers 322 may, for example, correspond to the dielectric layers 120 of FIG. 1, and/or the plurality of etch stop layers 324 may, for example, correspond to the dielectric substrate 114 of FIG. 1. The plurality of interconnect dielectric layers 322 are alternatingly stacked with the plurality of etch stop layers 324 from the bottom of the BEOL interconnect structure 316 to the top of the BEOL interconnect structure 316.

The dielectric stack further comprises a plurality of gate dielectric layers 110 and a plurality of hydrogen blocking layers 122. The plurality of gate dielectric layers 110 correspond to the plurality of TFTs 102 and are as their counterpart is described with regard to FIG. 1. Similarly, the plurality of hydrogen blocking layers 122 correspond to the plurality of TFTs 102 and are as their counterpart is described with regard to FIG. 1.

With reference to FIG. 4, a cross-sectional view 400 of some alternative embodiments of the TFT 102 of FIG. 1 is provided in which the conductive liner 118 is omitted. As such, the hydrogen absorption layer 104 directly contacts the dielectric substrate 114 and further directly contacts the lower one of the dielectric layers 120.

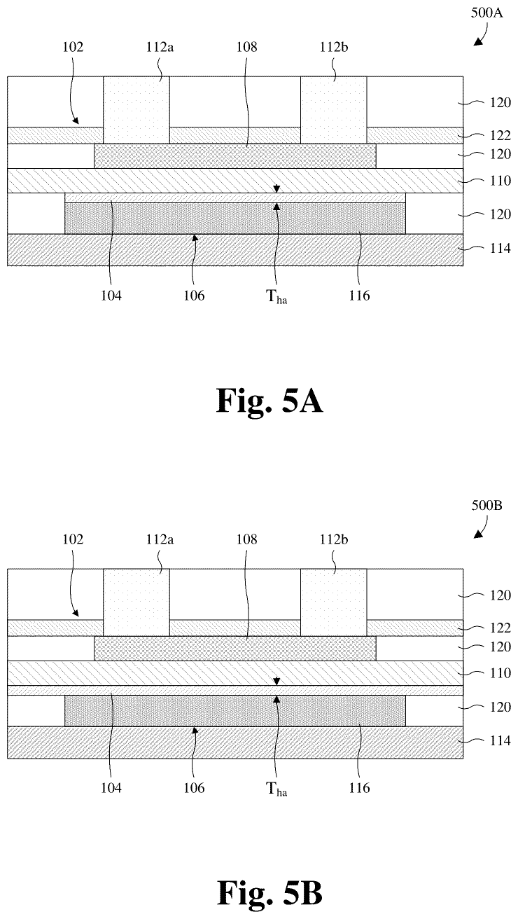

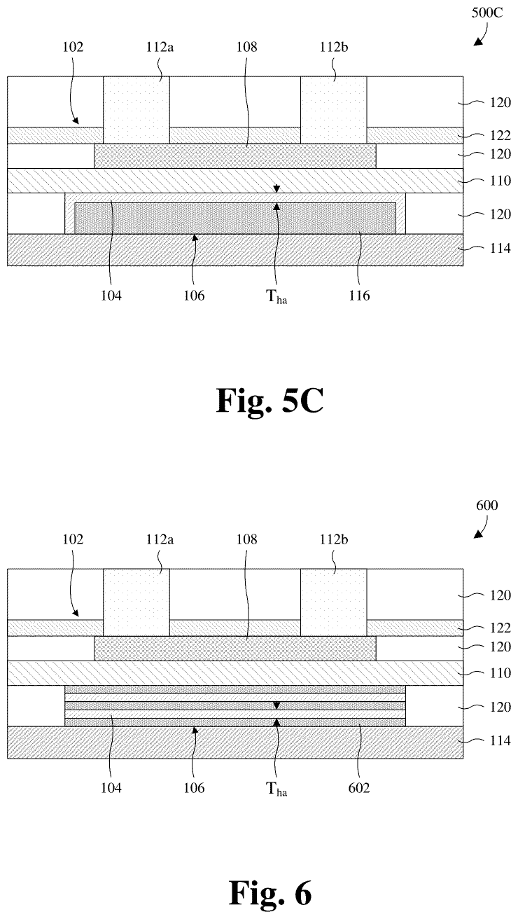

With reference to FIGS. 5A-5C, cross-sectional views 500A-500C of some alternative embodiments of the TFT 102 of FIG. 4 are provided in which the hydrogen absorption layer 104 has different layouts and/or positioning relative to the conductive body 116.

In the cross-sectional view 500A of FIG. 5A, the hydrogen absorption layer 104 is localized to a top surface of the conductive body 116 and separates the conductive body 116 from the gate dielectric layer 110. Further, the hydrogen absorption layer 104 and the conductive body 116 share a common width and form common sidewalls respectively on opposite sides of the conductive body 116.

In the cross-sectional view 500B of FIG. 5B, the hydrogen absorption layer 104 is localized over a top surface of the conductive body 116. Further, the hydrogen absorption layer 104 extends laterally beyond the conductive body 116 and has a width greater than a width of the conductive body 116. In some embodiments, the hydrogen absorption layer 104 shares a common width with the gate dielectric layer 110 and/or the hydrogen blocking layer 122.

In the cross-sectional view 500C of FIG. 5C, the hydrogen absorption layer 104 overlies the conductive body 116 and extends along sidewalls of the conductive body 116. Further, the hydrogen absorption layer 104 separates the conductive body 116 from the gate dielectric layer 110.

With reference to FIG. 6, a cross-sectional view 600 of some alternative embodiments of the TFT 102 of FIG. 1 is provided in which a plurality of conductive layers 602 form the gate electrode 106 and are alternating stacked with a plurality of hydrogen absorption layers 104. As such, the conductive body 116 and the conductive liner 118 are omitted.

The plurality of conductive layers 602 have N=3 layers, whereas the plurality of hydrogen absorption layers 104 have N−1 layers. While N is 3, N may be 4, 5, 6, or some other suitable integer value in alternative embodiments. Further, the plurality of conductive layers 602 and the plurality of hydrogen absorption layers 104 share a common width and form common sidewalls respectively on opposite sides of the gate electrode 106. The plurality of conductive layers 602 may, for example, be or comprise metal and/or some other suitable conductive materials. The plurality of hydrogen absorption layers 104 may, for example, each be as their counterpart is described with regard to FIG. 1.

With reference to FIG. 7, a cross-sectional view 700 of some alternative embodiments of the TFT 102 of FIG. 1 is provided in which the gate electrode 106 overlies the semiconductor channel 108. Therefore, whereas the TFT 102 of FIG. 1 may be regarded as a bottom-gate TFT, the TFT 102 of FIG. 7 may be regarded as a top-gate TFT.

The hydrogen blocking layer 122 underlies the semiconductor channel 108 and, in contrast with FIG. 1, is spaced from the semiconductor channel 108. In alternative embodiments, the hydrogen blocking layer 122 contacts the semiconductor channel 108. Additionally, the first and second source/drain electrodes 112a, 112b extend through the dielectric substrate 114. For example, the first source/drain electrode 112a may extend through the dielectric substrate 114 to a wire of a BEOL interconnect structure (not shown) underlying the TFT 102.

While the top layout view 200 of FIG. 2 is described with regard to the cross-sectional view 100 of FIG. 1, it is to be appreciated that the top layout view 200 is applicable to the cross-sectional view 700 of FIG. 7. For example, the cross-sectional view 700 of FIG. 7 may be taken along line A-A′ in FIG. 2, and/or the top layout view 200 may be taken along line A-A′ in FIG. 7.

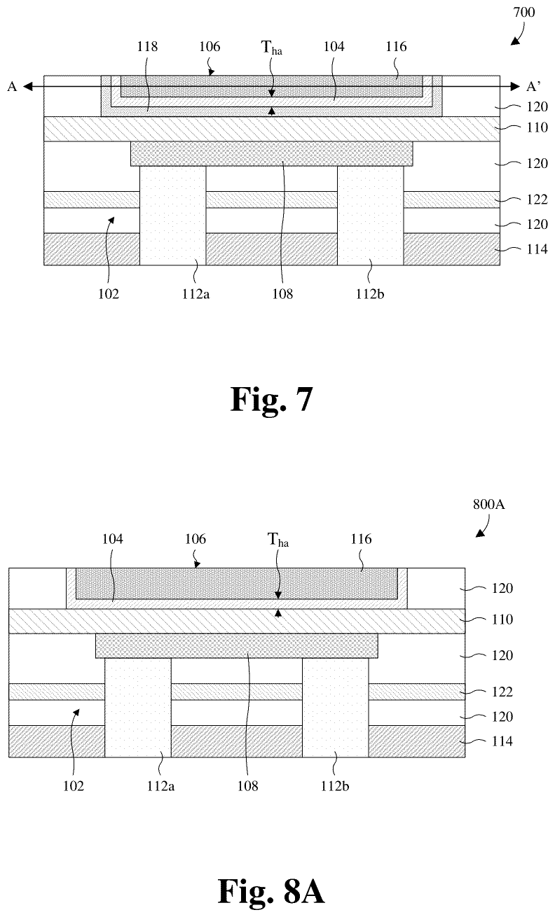

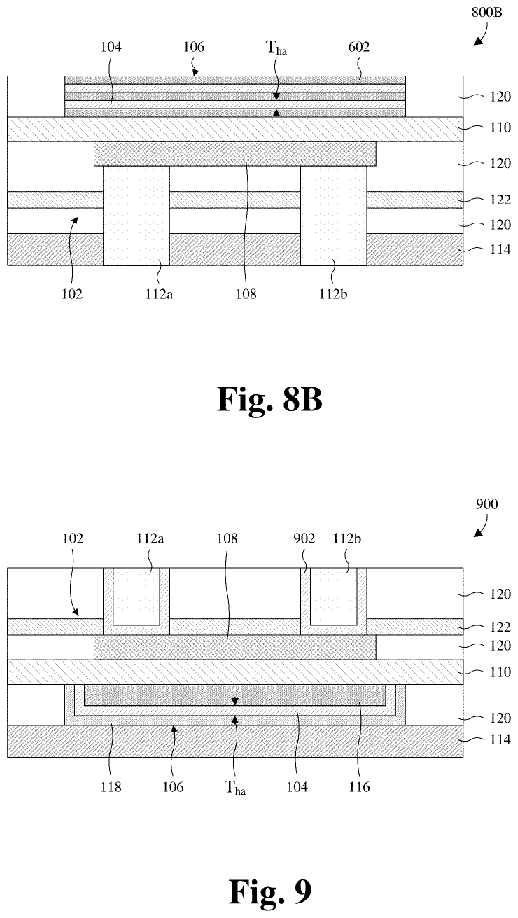

With reference to FIGS. 8A and 8B, cross-sectional views 800A, 800B of some alternative embodiments of the TFT 102 of FIG. 7 are provided. In the cross-sectional view 800A of FIG. 8A, the conductive liner 118 is omitted, such that the gate electrode 106 is as in FIG. 4. In the cross-sectional view 800B of FIG. 8B, the gate electrode 106 is as in FIG. 6. As such, the gate electrode 106 is formed by a plurality of conductive layers 602, which are alternatingly stacked with a plurality of hydrogen absorption layers 104. In yet additional alternative embodiments of the TFT 102 of FIG. 7, the gate electrode 106 is as in any one or combination of FIGS. 5A-5C.

With reference to FIG. 9, a cross-sectional view 900 of some alternative embodiments of the TFT 102 of FIG. 1 is provided in which the TFT 102 comprises a pair of additional hydrogen absorption layers 902 respectively at the first and second source/drain electrodes 112a, 112b. The pair of additional hydrogen absorption layers 902 are each individually as the hydrogen absorption layer 104 is described with regard to FIG. 1. Further, the pair of additional hydrogen absorption layers 902 respectively extend along bottoms surfaces and sidewalls of the first and second source/drain electrodes 112a, 112b.

The pair of additional hydrogen absorption layers 902 absorb and trap hydrogen migrating towards the semiconductor channel 108. Hence, the pair of additional hydrogen absorption layers 902 may prevent hydrogen from reaching and interacting with the semiconductor channel 108. As described with regard to FIG. 1, this may reduce hydrogen-based performance and/or reliability degradation of the TFT 102.

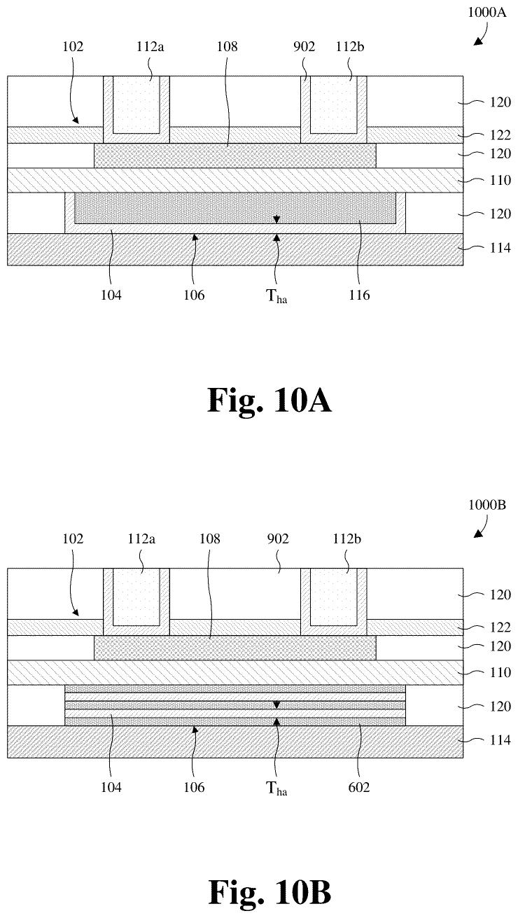

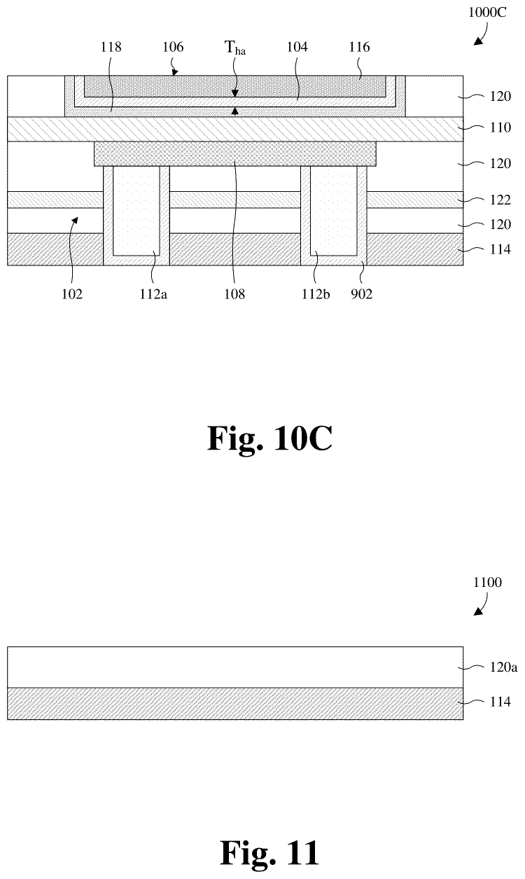

With reference to FIGS. 10A-10C, cross-sectional views 1000A-1000C of some alternative embodiments of the TFT 102 of FIG. 9 are provided. In the cross-sectional view 1000A of FIG. 10A, the gate electrode 106 is as in FIG. 4. In the cross-sectional view 1000B of FIG. 10B, the gate electrode 106 is as in FIG. 6. In the cross-sectional view 1000C of FIG. 10C, the gate electrode 106 overlies the semiconductor channel 108 as in FIG. 7. In yet additional alternative embodiments of the TFT 102 of FIG. 9, the gate electrode 106 is as in any one or combination of FIGS. 5A-5C and/or as in any one or combinations of FIGS. 8A and 8B.

While the plurality of TFTs 102 of FIG. 3 are each individually configured according to the TFT embodiments of FIG. 1, any one, two, or more of the plurality of TFTs 102 may alternatively be configured according to the TFT embodiments in any of or combination of FIGS. 4, 5A-5C, 6, 7, 8A, 8B, 9, and 10A-10C. For example, the first TFT 102a of FIG. 3 may be configured according to the TFT embodiments of FIG. 1, the second TFT 102b of FIG. 3 may be configured according to the TFT embodiments of FIG. 6, and the third TFT 102c of FIG. 3 may be configured according to the TFT embodiments of FIG. 9.

With reference to FIGS. 11-22, a series of cross-sectional views 1100-2200 of some embodiments of a method for forming a TFT with a hydrogen absorption layer is provided. The method may, for example, be employed to form the TFT 102 of FIG. 1.

As illustrated by the cross-sectional view 1100 of FIG. 11, a first dielectric layer 120a is deposited overlying a dielectric substrate 114. The first dielectric layer 120a may, for example, be or comprise a low k dielectric layer and/or some other suitable dielectric material(s).

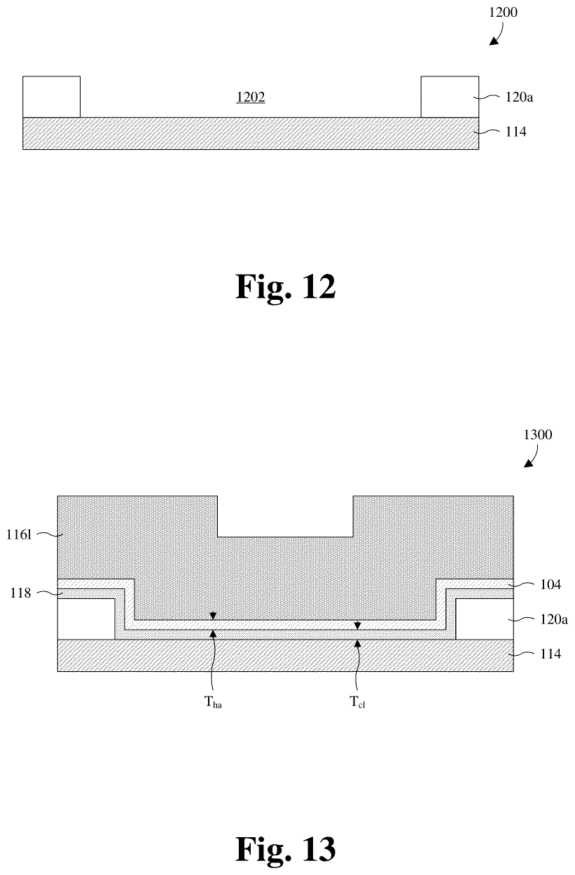

As illustrated by the cross-sectional view 1200 of FIG. 12, the first dielectric layer 120a is patterned to form a gate opening 1202 exposing the dielectric substrate 114. The patterning may, for example, be performed by a photolithography/etching process or the like.

As illustrated by the cross-sectional view 1300 of FIG. 13, a first conductive layer 1181, a hydrogen absorption layer 104, and a second conductive layer 1161 are deposited stacked over the first dielectric layer 120a and lining the gate opening 1202. In alternative embodiments, the first conductive layer 1181 is omitted to form a TFT as in FIG. 4. Further, in some embodiments, the first conductive layer 1181 is configured to prevent outward diffusion of material from the second conductive layer 1161. The hydrogen absorption layer 104 overlies the first conductive layer 1181. Further, the hydrogen absorption layer 104 is conductive and is configured to absorb hydrogen and, in some embodiments, other errant particles. The second conductive layer 1161 overlies the hydrogen absorption layer 104.

In some embodiments, the hydrogen absorption layer 104 is or comprises a noble metal, indium gallium zinc oxide (e.g., InGaZnO), an n-type metal oxide, or the like with a propensity to absorb hydrogen. The noble metal may, for example, have a nanocrystalline structure that facilitates absorption and trapping of hydrogen. The noble metal may, for example, be or comprise platinum (e.g., Pt), silver (e.g., Ag), palladium (e.g., Pd), gold (e.g., Au), the like, or any combination of the foregoing.

In some embodiments, the n-type metal oxide is or comprise an indium-oxide based semiconductor that is doped with n-type dopants. The indium-oxide based semiconductor may, for example, be or comprise InₓM_{y}O, wherein M is an element and x and y are numerical values. In some embodiments, the element is tungsten (e.g., W), titanium (e.g., Ti), gallium (e.g., Ga), zinc (e.g., Zn), calcium (e.g., Ca), magnesium (e.g., Mg), tin (e.g., Sn), a rare-earth element, or the like. In some embodiments, a ratio of x to y (e.g., x/y) is greater than zero and less than 1. Other suitable values are, however, amenable for the ratio.

In some embodiments, the n-type metal oxide (e.g., the indium-oxide based semiconductor described above) is doped with n-type dopants to a high concentration greater than 1E19 atoms per cubic centimeter (e.g., atoms/cm³) so as not to materially increase resistance of a gate electrode being formed. Further, in some embodiments, the n-type metal oxide has a carrier concentration that is about 1E19 atoms/cm³ to 1E21 atoms/cm³. Other suitable carrier concentrations are, however, amenable in alternative embodiments.

In some embodiments, a thickness Tₕₐ of the hydrogen absorption layer 104 is about 5-20 nanometers, about 5-10 nanometers, about 10-15 nanometers, about 15-20 nanometers, or some other suitable value or range of values. In some embodiments, a thickness T_{cl} of the first conductive layer 1181 is or comprises 1-5 nanometers or some other suitable value or range of values.

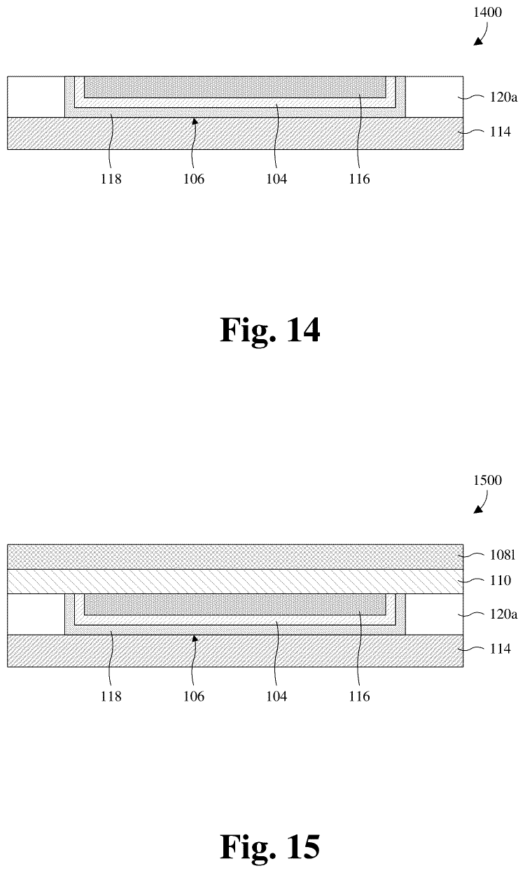

As illustrated by the cross-sectional view 1400 of FIG. 14, a planarization is performed into the first conductive layer 1181, the hydrogen absorption layer 104, and the second conductive layer 1161 to clear these layers from atop the first dielectric layer 120a. The planarization further forms a gate electrode 106 in the gate opening 1202 (see, e.g., FIG. 12). The planarization may, for example, be performed by a chemical mechanical polish (CMP) or the like.

The gate electrode 106 comprises a portion of the second conductive layer 1161, which is hereafter referred to as a conductive body 116. Further, the gate electrode 106 comprises a portion of the first conductive layer 1181, which is hereafter referred to as a conductive liner 118. The conductive liner 118 wraps around a bottom of the conductive body 116 and is separated from the conductive body 116 by a portion of the hydrogen absorption layer 104. In some embodiments, a top layout of the gate electrode 106 is as in FIG. 2.

As illustrated by the cross-sectional view 1500 of FIG. 15, a gate dielectric layer 110 and a semiconductor layer 1081 are deposited stacked over the gate electrode 106 and the first dielectric layer 120a. The gate dielectric layer 110 is deposited first and hence underlies the semiconductor layer 1081. The gate dielectric layer 110 may, for example, be or comprise a high k dielectric material and/or some other suitable dielectric material(s).

The semiconductor layer 1081 is sensitive to hydrogen. Such sensitivity may lead to performance and/or reliability degradation of the TFT being formed in response to exposure of the semiconductor layer 1081 to hydrogen. For example, exposure may decrease ON current (e.g., I_{ON}) of the TFT. As another example, exposure may increase threshold-voltage variation while the TFT is under thermal stress and/or some other suitable type of stress. The semiconductor layer 1081 may, for example, be or comprise indium zinc oxide (e.g., IZO), indium tin oxide (e.g., ITO), indium oxide (e.g., In₂O₃), gallium oxide (e.g., Ga₂O₃), indium gallium zinc oxide (e.g., InGaZnO), zinc oxide (e.g., ZnO), aluminum zinc oxide (e.g., Al₂O₅Zn₂), aluminum-doped zinc oxide (e.g., AZO), indium tungsten oxide (e.g., IWO), titanium oxide (e.g., TiOx), the like, or any combination of the foregoing.

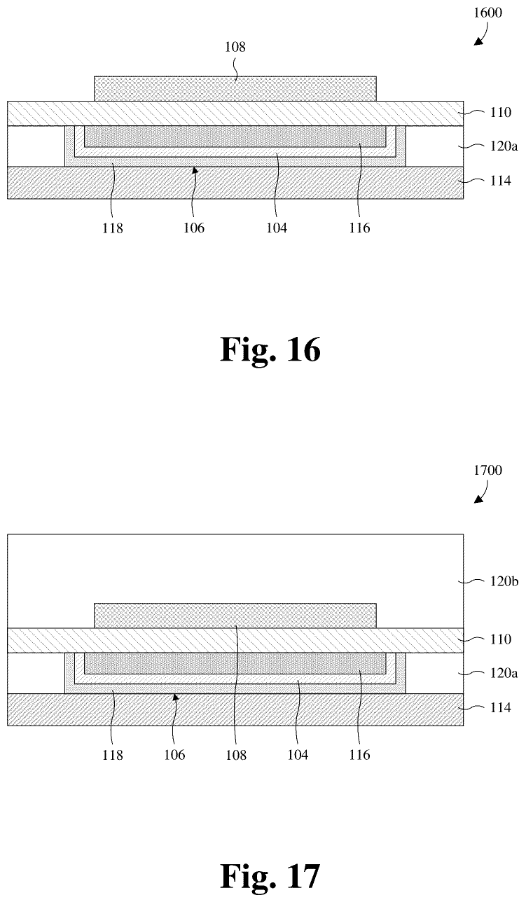

As illustrated by the cross-sectional view 1600 of FIG. 16, the semiconductor layer 1081 is patterned to form a semiconductor channel 108 overlying the gate electrode 106. The semiconductor channel 108 corresponds to a portion of the semiconductor layer 1081. Further, the semiconductor channel 108 has a width less than a width of the conductive body 116 and, in some embodiments, may be regarded as a semiconductor island, semiconductor body, or the like. In some embodiments, the semiconductor channel 108 and the gate electrode 106 have top layouts as in FIG. 2. Further, in some embodiments, the semiconductor channel 108 is confined to an area of the gate electrode 106 when viewed top down. The patterning may, for example, be performed by a photolithography/etching process or the like.

As noted above, the semiconductor layer 1081 is sensitive to hydrogen. Hence, the semiconductor channel 108 is sensitive to hydrogen. Because the hydrogen absorption layer 104 is embedded in the gate electrode 106, the hydrogen absorption layer 104 is proximate to the semiconductor channel 108. This proximity, together with a propensity to absorb hydrogen, allows the hydrogen absorption layer 104 to absorb and prevent hydrogen from migrating to and interacting with the semiconductor channel 108. This may, in turn, enhance performance of the TFT being formed and enhance reliability of the TFT.

As illustrated by the cross-sectional view 1700 of FIG. 17, a second dielectric layer 120b is deposited overlying the gate dielectric layer 110 and the semiconductor channel 108. The second dielectric layer 120b may, for example, be or comprise the same dielectric material as the first dielectric layer 120a and/or some other suitable dielectric material(s).

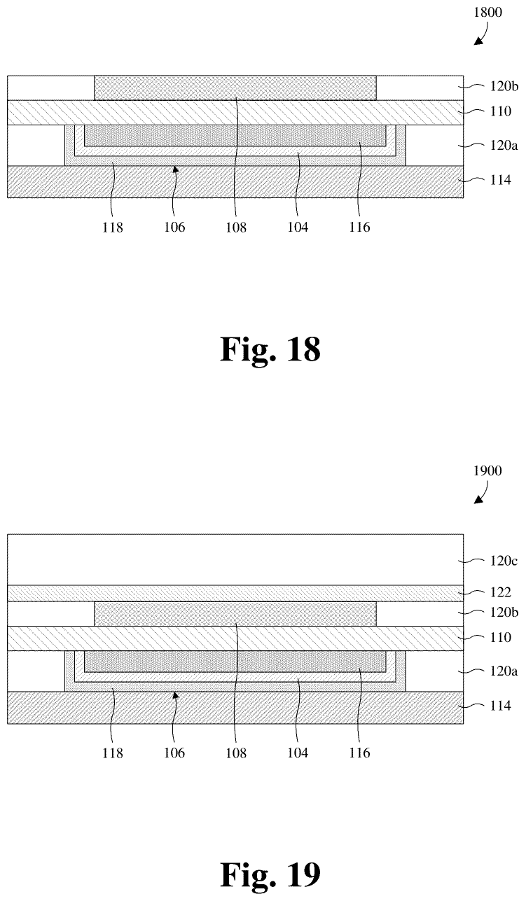

As illustrated by the cross-sectional view 1800 of FIG. 18, a planarization is performed into the second dielectric layer 120b to clear the second dielectric layer 120b from atop the semiconductor channel 108 and to expose the semiconductor channel 108. The planarization may, for example, be performed by a CMP or the like.

As illustrated by the cross-sectional view 1900 of FIG. 19, a hydrogen blocking layer 122 and a third dielectric layer 120c are deposited over the second dielectric layer 120b and the semiconductor channel 108. The hydrogen blocking layer 122 is dielectric and underlies the third dielectric layer 120c. Further, the hydrogen blocking layer 122 is configured to block hydrogen over the hydrogen blocking layer 122 from reaching the semiconductor channel 108. The third dielectric layer 120c may, for example, be or comprise the same dielectric material as the first dielectric layer 120a and/or the second dielectric layer 120b. Alternatively, the third dielectric layer 120c may, for example, be or comprise some other suitable dielectric material(s).

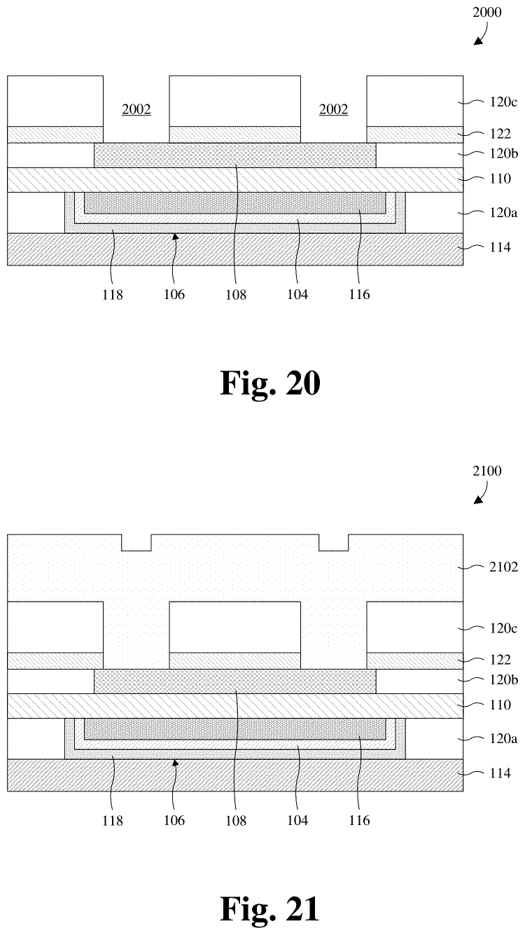

As illustrated by the cross-sectional view 2000 of FIG. 20, the third dielectric layer 120c and the hydrogen blocking layer 122 are patterned to form a pair of source/drain openings 2002 extending to the semiconductor channel 108 and respectively on opposite sides of the semiconductor channel 108. In some embodiments, the semiconductor channel 108 has a top layout as in FIG. 2, and the pair of source/drain openings 2002 have individual top layouts respectively as individual top layouts of the first and second source/drain electrodes 112a, 112b in FIG. 2. Further, in some embodiments, the pair of source/drain openings 2002 are confined to an area of the semiconductor channel 108 when viewed top down. The patterning may, for example, be performed by a photolithography/etching process or the like.

As illustrated by the cross-sectional view 2100 of FIG. 21, a conductive layer 2102 is deposited overlying the third dielectric layer 120c and filling the pair of source/drain openings 2002. In some embodiments, a top of the conductive layer 2102 is indented directly over each of the pair of source/drain openings 2002.

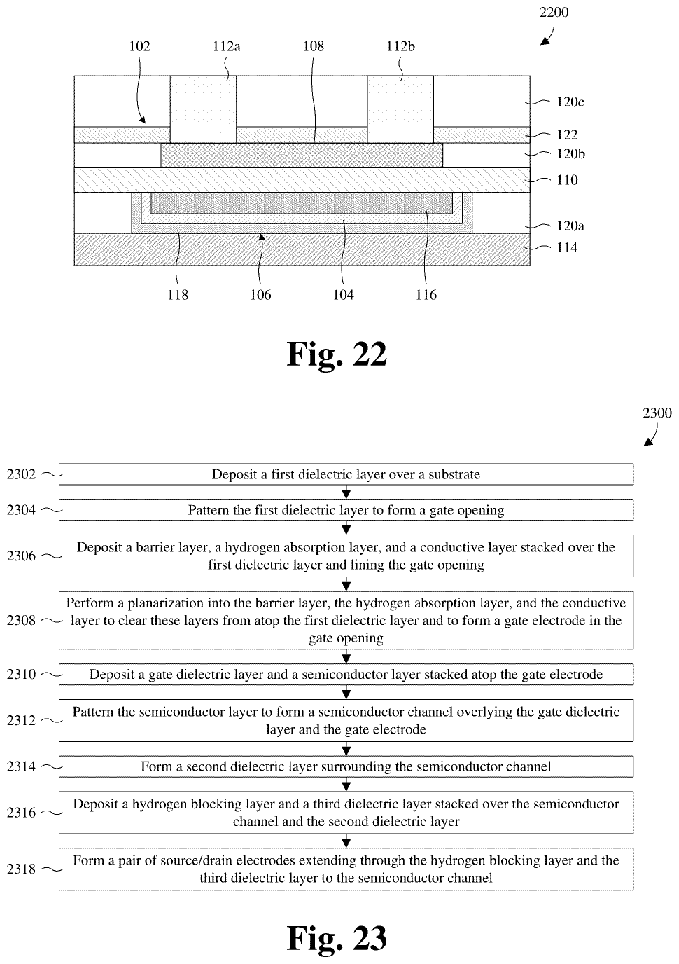

As illustrated by the cross-sectional view 2200 of FIG. 22, a planarization is performed into the conductive layer 2102 to clear the conductive layer 2102 from atop the third dielectric layer 120c and to expose the third dielectric layer 120c. This, in turn, forms a first source/drain electrode 112a and a second source/drain electrode 112b respectively in the pair of source/drain openings 2002 (see, e.g., FIG. 20). Source/drain electrode(s) may refer to a source electrode or a drain electrode, individually or collectively dependent upon the context. Collectively, the first and second source/drain electrodes 112a, 112b, the semiconductor channel 108, the gate dielectric layer 110, the gate electrode 106, and the hydrogen absorption layer 104 form a TFT 102. The planarization may, for example, be performed by a CMP or the like.

While FIGS. 11-22 are described with reference to a method, it will be appreciated that the structures shown in these figures are not limited to the method but rather may stand alone separate of the method. While FIGS. 11-22 are described as a series of acts, it will be appreciated that the order of the acts may be altered in other embodiments. While FIGS. 11-22 illustrate and describe as a specific set of acts, some acts that are illustrated and/or described may be omitted in other embodiments. Further, acts that are not illustrated and/or described may be included in other embodiments.

With reference to FIG. 23, a block diagram 2300 of some embodiments of the method of FIGS. 11-22 is provided.

At act 2302, a first dielectric layer is deposited over a substrate. See, for example, FIG. 11.

At act 2304, the first dielectric layer is patterned to form a gate opening. See, for example, FIG. 12.

At act 2306, a barrier layer, a hydrogen absorption layer, and a conductive layer are deposited stacked over the first dielectric layer and lining the gate opening. See, for example, FIG. 13.

At act 2308, a planarization is performed into the barrier layer, the hydrogen absorption layer, and the conductive layer to clear these layers from atop the first dielectric layer and to form a gate electrode in the gate opening. See, for example, FIG. 14.

At act 2310, a gate dielectric layer and a semiconductor layer are deposited stacked atop the gate electrode. See, for example, FIG. 15.

At act 2312, the semiconductor layer is patterned to form a semiconductor channel overlying the gate dielectric layer and the gate electrode. See, for example, FIG. 16.

At act 2314, a second dielectric layer is formed surrounding the semiconductor channel. See, for example, FIGS. 17 and 18. In some embodiments, formation of the second dielectric layer comprises depositing the second dielectric layer and subsequently performing a planarization into the second dielectric layer.

At act 2316, a hydrogen blocking layer and a third dielectric layer are deposited stacked over the semiconductor channel and the second dielectric layer. See, for example, FIG. 19.

At act 2318, a pair of source/drain electrodes are formed extending through the hydrogen blocking layer and the third dielectric layer to the semiconductor channel. See, for example, FIGS. 20-22.

While the block diagram 2300 of FIG. 23 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

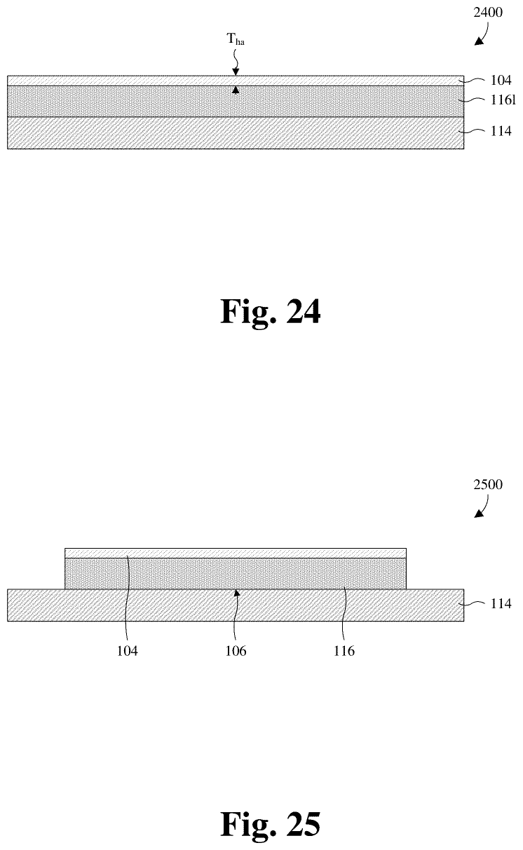

With reference to FIGS. 24-27, a series of cross-sectional views 2400-2700 of some first alternative embodiments of the method of FIGS. 11-22 is provided. The first alternative embodiments may, for example, be employed to form the TFT 102 of FIG. 5A.

As illustrated by the cross-sectional view 2400 of FIG. 24, a conductive layer 1161 and a hydrogen absorption layer 104 are deposited stacked over a dielectric substrate 114. The hydrogen absorption layer 104 overlies the conductive layer 1161. Further, the hydrogen absorption layer 104 is conductive and is configured to absorb hydrogen. The hydrogen absorption layer 104 may, for example, be as described with regard to FIG. 13.

As illustrated by the cross-sectional view 2500 of FIG. 25, the conductive layer 1161 and the hydrogen absorption layer 104 are patterned to form a gate electrode 106. The gate electrode 106 comprises a portion of the conductive layer 1161, which is hereafter referred to as a conductive body 116, and further comprises a portion of the hydrogen absorption layer 104 that overlies the conductive body 116. The patterning may, for example, be performed by a photolithography/etching process or the like.

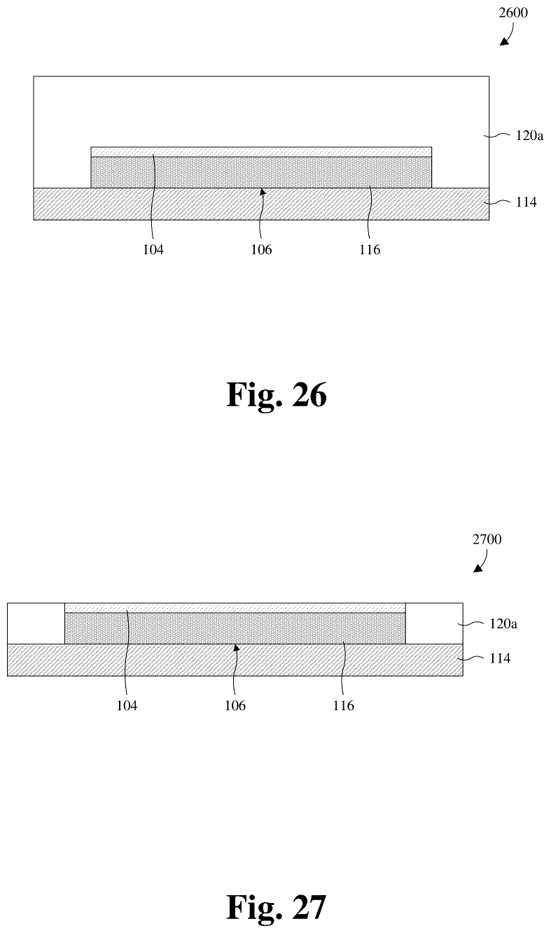

As illustrated by the cross-sectional view 2600 of FIG. 26, a first dielectric layer 120a is deposited over the gate electrode 106.

As illustrated by the cross-sectional view 2700 of FIG. 27, a planarization is performed into the first dielectric layer 120a to clear the first dielectric layer 120a from atop the gate electrode 106 and to expose the hydrogen absorption layer 104. The planarization may, for example, be performed by a CMP or the like. After the planarization, the acts described with regard to FIGS. 15-22 may be performed to form a TFT as in FIG. 5A.

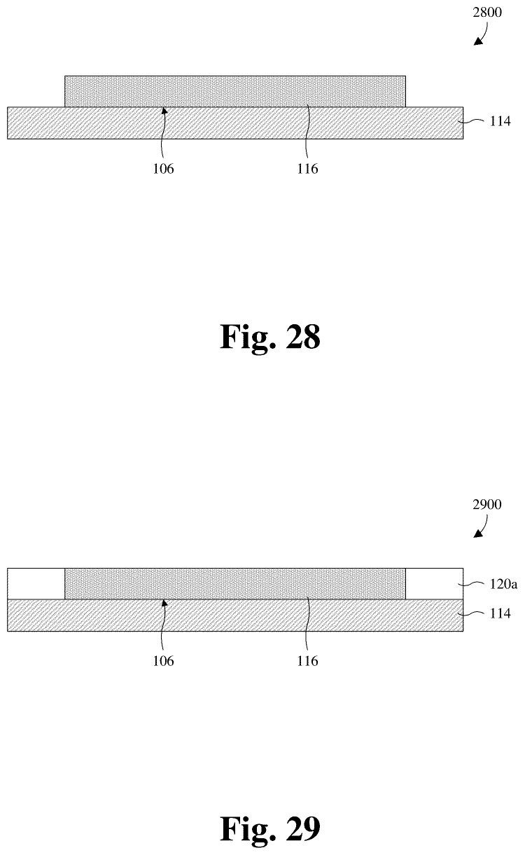

With reference to FIGS. 28-30, a series of cross-sectional views 2800-3000 of some second alternative embodiments of the method of FIGS. 11-22 is provided. The second alternative embodiments may, for example, be employed to form the TFT 102 of FIG. 5B.

As illustrated by the cross-sectional view 2800 of FIG. 28, a conductive layer 1161 is deposited over a dielectric substrate 114 and is subsequently patterned into a conductive body 116, which forms a gate electrode 106. The patterning may, for example, be performed by a photolithography/etching process or the like.

As illustrated by the cross-sectional view 2900 of FIG. 29, the first dielectric layer 120a is deposited over the gate electrode 106 and is subsequently planarized. The first dielectric layer 120a may, for example, be deposited as in FIG. 26. The planarization clears the first dielectric layer 120a from atop the gate electrode 106 and exposes the gate electrode 106. The planarization may, for example, be performed by a CMP or the like.

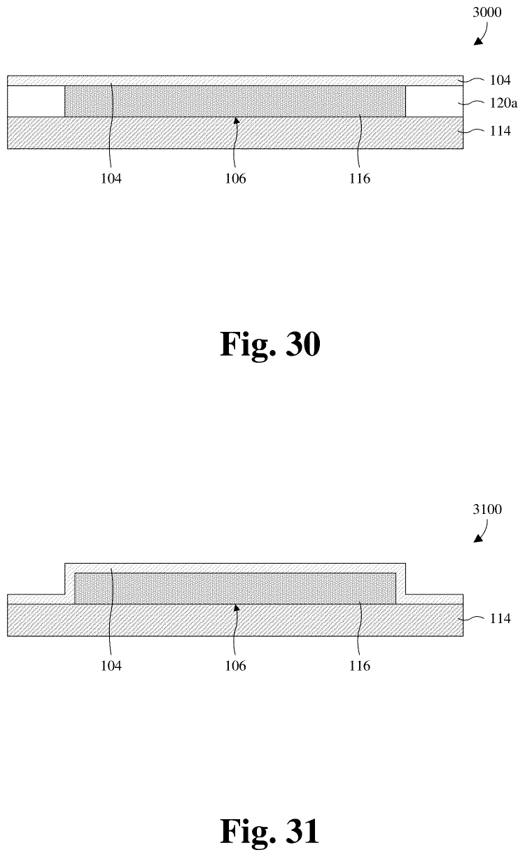

As illustrated by the cross-sectional view 3000 of FIG. 30, a hydrogen absorption layer 104 is deposited over the gate electrode 106 and the first dielectric layer 120a. The hydrogen absorption layer 104 may, for example, be as described with regard to FIG. 13. After the deposition of the hydrogen absorption layer 104, the acts described with regard to FIGS. 15-22 may be performed to form a TFT as in FIG. 5B.

With reference to FIGS. 31-33, a series of cross-sectional views 3100-3300 of some third alternative embodiments of the method of FIGS. 11-22 is provided. The third alternative embodiments may, for example, be employed to form the TFT 102 of FIG. 5C.

As illustrated by the cross-sectional view 3100 of FIG. 31, a conductive layer 1161 is deposited over a dielectric substrate 114 and is subsequently patterned into a conductive body 116, which forms a gate electrode 106. The patterning may, for example, be performed by a photolithography/etching process or the like.

Also illustrated by the cross-sectional view 3100 of FIG. 31, a hydrogen absorption layer 104 is deposited over the gate electrode 106. The hydrogen absorption layer 104 extends along a top surface of the gate electrode 106 and a top surface of the dielectric substrate 114. Further, the hydrogen absorption layer 104 extends along sidewalls of the gate electrode 106. The hydrogen absorption layer 104 may, for example, be as described with regard to FIG. 13.

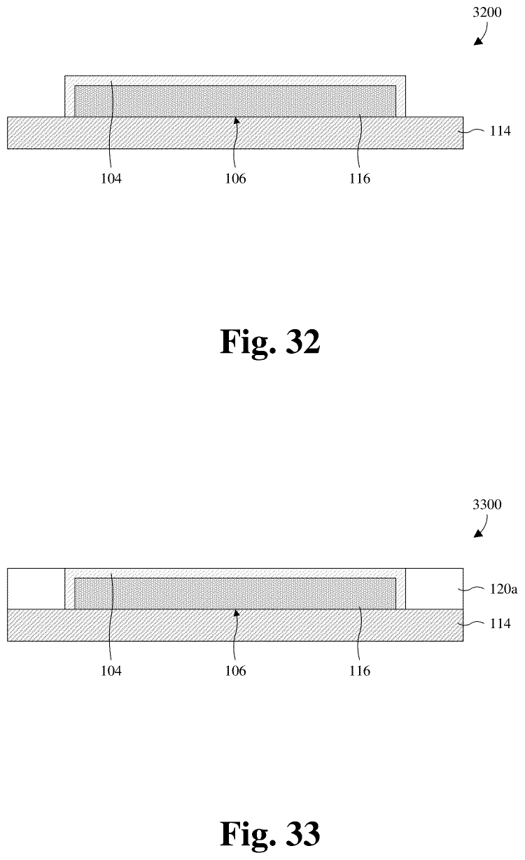

As illustrated by the cross-sectional view 3200 of FIG. 32, the hydrogen absorption layer 104 is patterned to clear the hydrogen absorption layer 104 from the top surface of dielectric substrate 114. The patterning may, for example, be performed by a photolithography/etching process or the like.

As illustrated by the cross-sectional view 3300 of FIG. 33, the first dielectric layer 120a is deposited over the hydrogen absorption layer 104 and is subsequently planarized. The first dielectric layer 120a may, for example, be deposited as in FIG. 26. The planarization clears the first dielectric layer 120a from atop the hydrogen absorption layer 104 and may, for example, be performed by a CMP or the like. After the planarization, the acts described with regard to FIGS. 15-22 may be performed to form a TFT as in FIG. 5C.

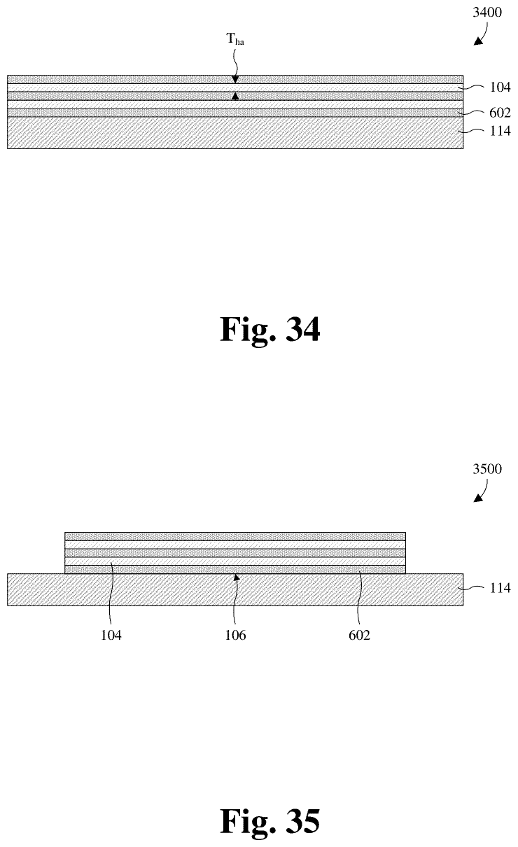

With reference to FIGS. 34-36, a series of cross-sectional views 3400-3600 of some fourth alternative embodiments of the method of FIGS. 11-22 is provided. The fourth alternative embodiments may, for example, be employed to form the TFT 102 of FIG. 6.

As illustrated by the cross-sectional view 3400 of FIG. 34, a plurality of hydrogen absorption layers 104 and a plurality of conductive layers 602 are deposited alternatingly stacked. The plurality of conductive layers 602 have N=3 layers, and the plurality of hydrogen absorption layers 104 have N−1 layers. However, in alternative embodiments, N may be 4, 5, 6, or some other suitable integer value. Further, the plurality of hydrogen absorption layers 104 are conductive and are configured to absorb hydrogen. The plurality of hydrogen absorption layers 104 may, for example, each be as their counterpart is described with regard to FIG. 13.

As illustrated by the cross-sectional view 3500 of FIG. 35, the plurality of hydrogen absorption layers 104 and the plurality of conductive layers 602 are patterned to form a gate electrode 106. The gate electrode 106 comprises portions of the conductive layers 602, which are alternatingly stacked with portions of the hydrogen absorption layers 104. The patterning may, for example, be performed by a photolithography/etching process or the like.

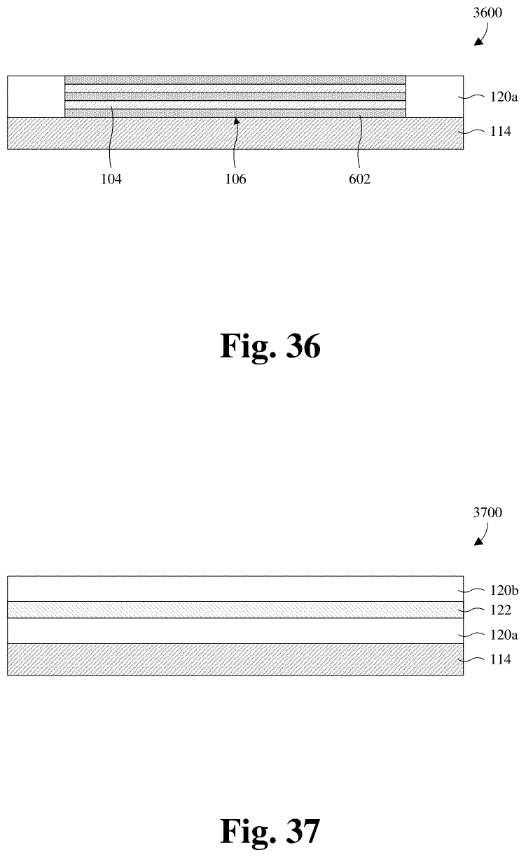

As illustrated by the cross-sectional view 3600 of FIG. 36, a first dielectric layer 120a is deposited over the gate electrode 106 and is subsequently planarized. The first dielectric layer 120a may, for example, be deposited as in FIG. 26. The planarization clears the first dielectric layer 120a from atop the gate electrode 106 and may, for example, be performed by a CMP or the like. After the planarization, the acts described with regard to FIGS. 15-22 may be performed to form a TFT as in FIG. 6.

With reference to FIGS. 37-42, a series of cross-sectional views 3700-4200 of some fifth alternative embodiments of the method of FIGS. 11-22 is provided. The fifth alternative embodiments may, for example, be employed to form the TFT 102 of FIG. 7.

As illustrated by the cross-sectional view 3700 of FIG. 37, a first dielectric layer 120a, a hydrogen blocking layer 122, and a second dielectric layer 120b are deposited stacked over a dielectric substrate 114. The hydrogen blocking layer 122 overlies the first dielectric layer 120a and is configured to block hydrogen. Further, the second dielectric layer 120b overlies the hydrogen blocking layer 122.

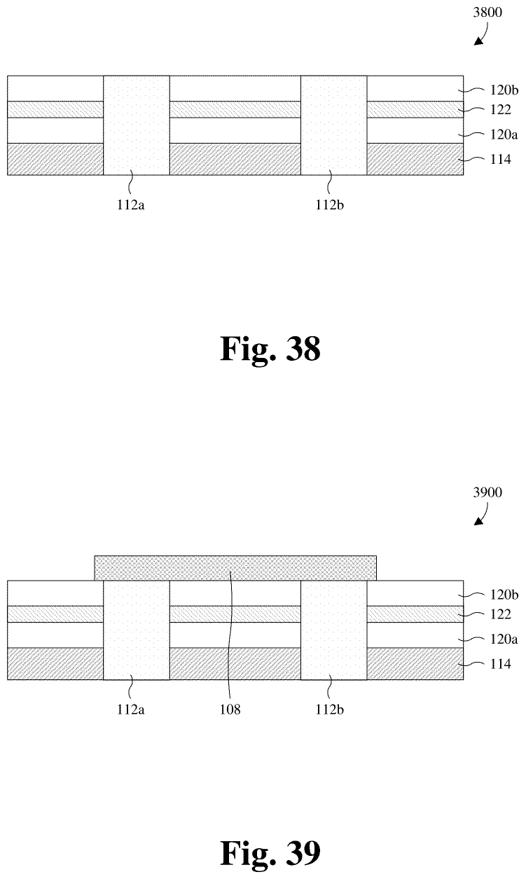

As illustrated by the cross-sectional view 3800 of FIG. 38, a first source/drain electrode 112a and a second source/drain electrode 112b are formed extending through the first dielectric layer 120a, the hydrogen blocking layer 122, the second dielectric layer 120b, and the dielectric substrate 114. The first and second source/drain electrodes 112a, 112b may, for example, extend to corresponding wires of a BEOL interconnect structure (not shown) underlying the dielectric substrate 114.

In some embodiments, the forming is performed according to the acts described at FIGS. 20-22. For example, the first dielectric layer 120a, the hydrogen blocking layer 122, the second dielectric layer 120b, and the dielectric substrate 114 may be patterned to form a pair of source/drain openings 2002 (see, e.g., FIG. 20). A conductive layer 2102 may then be deposited filling the pair of source/drain openings 2002 (see, e.g., FIG. 21). Further, a planarization may be performed into the conductive layer 2102 to clear the conductive layer 2102 from atop the second dielectric layer 120b and to expose the second dielectric layer 120b (see, e.g., FIG. 22).

As illustrated by the cross-sectional view 3900 of FIG. 39, a semiconductor channel 108 is formed atop the second dielectric layer 120b and the first and second source/drain electrodes 112a, 112b. In some embodiments, this forming is performed according to the acts described at FIGS. 15 and 16. For example, a semiconductor layer 1081 may be deposited and subsequently patterned into the semiconductor channel 108.

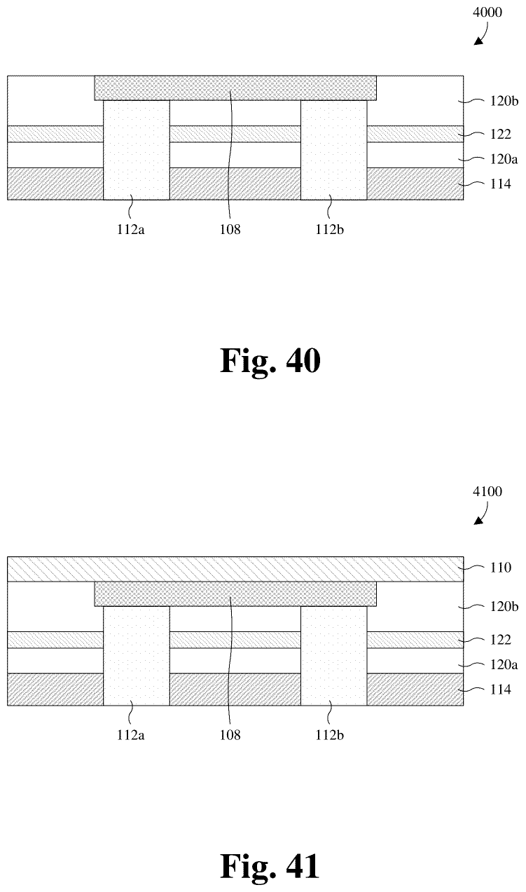

As illustrated by the cross-sectional view 4000 of FIG. 40, dielectric material is deposited to extend the second dielectric layer 120b over the semiconductor channel 108 and a planarization is subsequently performed to clear the second dielectric layer 120b from atop the semiconductor channel 108. This may, for example, be similar to how the first dielectric layer 120a is deposited and subsequently planarized in FIGS. 26 and 27.

As illustrated by the cross-sectional view 4100 of FIG. 41, a gate dielectric layer 110 is deposited over the semiconductor channel 108 and the second dielectric layer 120b.

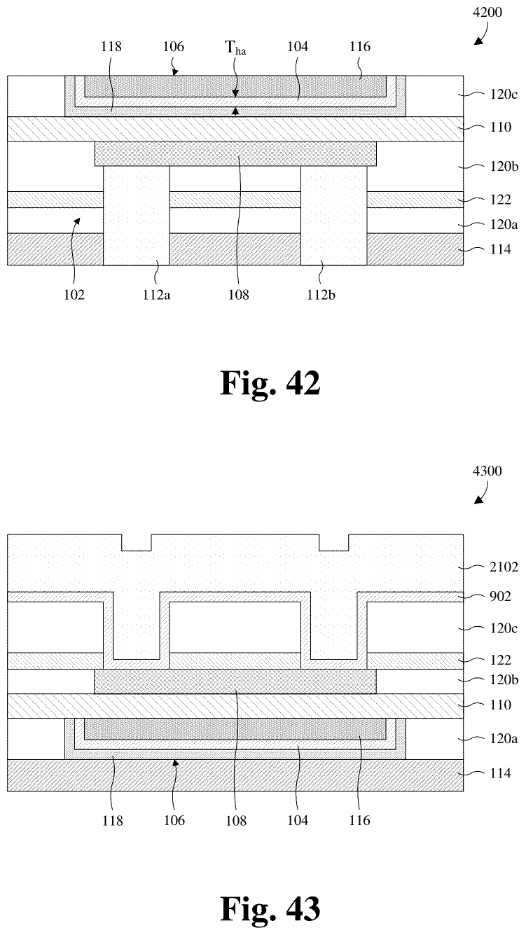

As illustrated by the cross-sectional view 4200 of FIG. 42, a gate electrode 106 and a third dielectric layer 120c are formed over the gate dielectric layer 110 according to the acts described at FIGS. 11-14, except the third dielectric layer 120c is used in place of the first dielectric layer 120a. In alternative embodiments, the gate electrode 106 and the third dielectric layer 120c are formed according to the acts described at FIGS. 24-27, the acts described at FIGS. 28-30, the acts described at FIGS. 31-33, or the acts described at FIGS. 34-36.

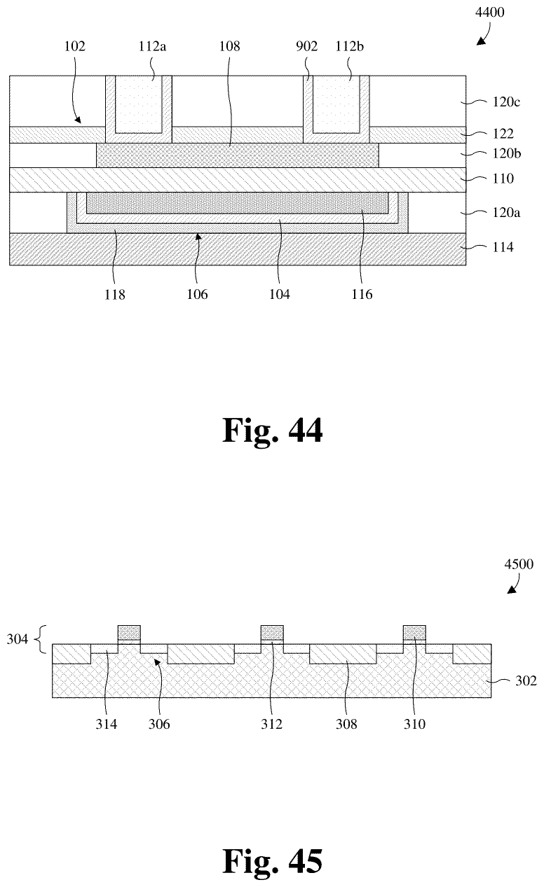

With reference to FIGS. 43 and 44, a series of cross-sectional views 4300, 4400 of some sixth alternative embodiments of the method of FIGS. 11-22 is provided. The sixth alternative embodiments may, for example, be employed to form the TFT 102 of FIG. 9.

As illustrated by the cross-sectional view 4300 of FIG. 43, the acts according to FIGS. 11-20 are performed to form the structure at FIG. 20. Further, an additional hydrogen absorption layer 902 and a conductive layer 2102 are deposited stacked overlying a third dielectric layer 120c and filling a pair of source/drain openings 2002. The additional hydrogen absorption layer 902 underlies the conductive layer 2102 and may, for example, be as the hydrogen absorption layer 104 is described with regard to FIG. 13.

As illustrated by the cross-sectional view 4400 of FIG. 44, a planarization is performed into the additional hydrogen absorption layer 902 and the conductive layer 2102 to clear these layers from atop the third dielectric layer 120c and to expose the third dielectric layer 120c. This, in turn, forms a first source/drain electrode 112a and a second source/drain electrode 112b lined by individual segments of the additional hydrogen absorption layer 902. These segments may themselves be referred to as additional hydrogen absorption layers. Collectively, the first and second source/drain electrodes 112a, 112b, a semiconductor channel 108, a gate dielectric layer 110, a gate electrode 106, and a hydrogen absorption layer 104 form a TFT 102. The planarization may, for example, be performed by a CMP or the like.

While FIGS. 24-44 are described with reference to a method, it will be appreciated that the structures shown in these figures are not limited to the method but rather may stand alone separate of the method. While FIGS. 24-44 are described as a series of acts, it will be appreciated that the order of the acts may be altered in other embodiments. While FIGS. 24-44 illustrate and describe as a specific set of acts, some acts that are illustrated and/or described may be omitted in other embodiments. Further, acts that are not illustrated and/or described may be included in other embodiments.

With reference to FIGS. 45-48, a series of cross-sectional views 4500-4800 of some embodiments of a method for forming an IC comprising a TFT with a hydrogen absorption layer is provided. The TFT may, for example, be as in FIG. 1.

As illustrated by the cross-sectional view 4500 of FIG. 45, a device layer 304 is formed on a semiconductor substrate 302. The device layer 304 includes a plurality of logic devices 306, partially formed by the semiconductor substrate 302 and separated from each other by an isolation structure 308. In some embodiments, the device layer 304 includes additional device types and/or may also be referred to as a FEOL layer.

The plurality of logic devices 306 comprise individual gate electrodes 310, individual gate dielectric layers 312, and individual pairs of source/drain regions 314. Source/drain region(s) may refer to a source region or a drain region, individually or collectively dependent upon the context. The pairs of source/drain regions 314 are inset into a top of the semiconductor substrate 302. The gate electrodes 310 respectively overlie the gate dielectric layers 312 and are respectively between the pairs of source/drain regions 314.

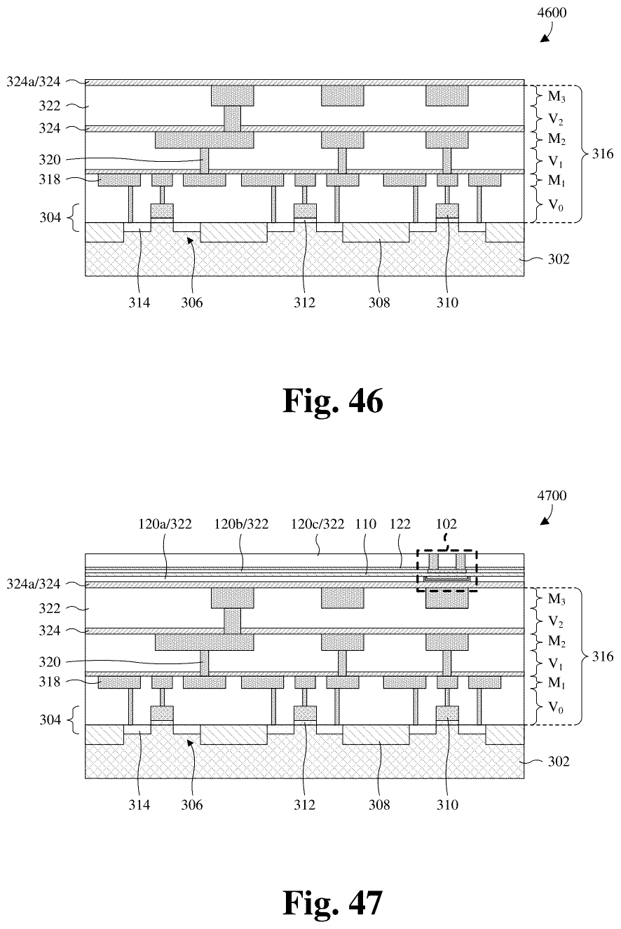

As illustrated by the cross-sectional view 4600 of FIG. 46, a BEOL interconnect structure 316 is partially formed overlying and electrically coupled to the plurality of logic devices 306. Further, a dielectric structure is partially formed around the BEOL interconnect structure 316. The dielectric comprises a plurality of interconnect dielectric layers 322 and a plurality of etch stop layers 324 that are alternatingly stacked. The plurality of etch stop layers 324 include a TFT-support etch stop layer 324a at a top of the dielectric structure. The BEOL interconnect structure 316 comprises a plurality of wires 318 and a plurality of vias 320.

The plurality of wires 318 are grouped into a plurality of wire levels, and the plurality of vias 320 are grouped into a plurality of via levels alternatingly stacked with the plurality of wire levels. The plurality of wire levels are labeled M₁, M₂, and M₃ away from the semiconductor substrate 302. Similarly, the plurality of via levels are labeled V₀, V₁, and V₂ away from the semiconductor substrate 302.

As illustrated by the cross-sectional view 4700 of FIG. 47, a TFT 102 is formed on the TFT-support etch stop layer 324a according to the method of FIGS. 11-22. The dielectric substrate 114 in the method of FIGS. 11-22 corresponds to the TFT-support etch stop layer 324a, and the first, second, and third dielectric layers 120a-120c correspond to interconnect dielectric layers 322. In alternative embodiments, the TFT 102 is formed according to the method of FIGS. 24-27, the method of FIGS. 28-30, the method of FIGS. 31-33, the method of FIGS. 34-36, the method of FIGS. 37-42, or the method of FIGS. 43 and 44.

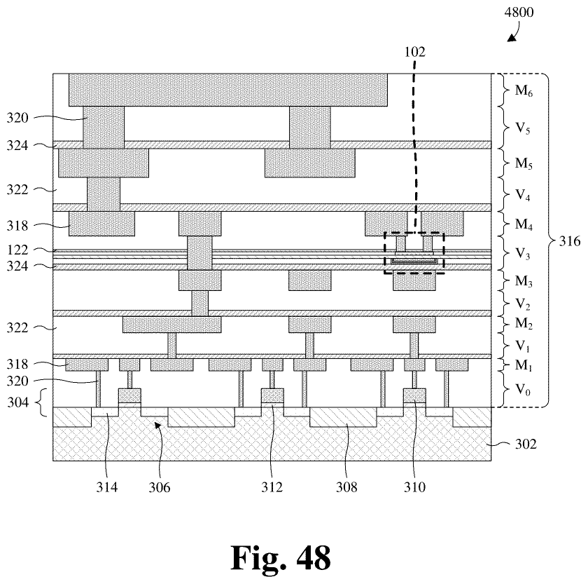

As illustrated by the cross-sectional view 4800 of FIG. 48, the BEOL interconnect structure 316 is completed over the TFT 102. Further, the dielectric structure is extended around the BEOL interconnect structure 316.

To extend the dielectric structure, a plurality of additional interconnect dielectric layers 322 and a plurality of additional etch stop layers 324 are formed alternatingly stacked. To complete the BEOL interconnect structure 316, a plurality of additional wires 318 and a plurality of additional vias 320 are formed. The plurality of additional wires 318 are grouped into a plurality of additional wire levels, and the plurality of additional vias 320 are grouped into a plurality of additional via levels alternatingly stacked with the plurality of additional wire levels. The plurality of additional wire levels are labeled M₄, M₅, and M₆ away from the semiconductor substrate 302. Similarly, the plurality of additional via levels are labeled V₃, V₄, and V₅ away from the semiconductor substrate 302.

While FIGS. 45-48 are described with reference to a method, it will be appreciated that the structures shown in these figures are not limited to the method but rather may stand alone separate of the method. While FIGS. 45-48 are described as a series of acts, it will be appreciated that the order of the acts may be altered in other embodiments. While FIGS. 45-48 illustrate and describe as a specific set of acts, some acts that are illustrated and/or described may be omitted in other embodiments. Further, acts that are not illustrated and/or described may be included in other embodiments.

In view of the foregoing, the present disclosure is directed to a TFT comprising a hydrogen absorption layer.

In some embodiments, the present disclosure provides a semiconductor device, including: a semiconductor channel; a first source/drain electrode and a second source/drain electrode that are at a first side of the semiconductor channel and that are electrically coupled respectively to different portions of the semiconductor channel; a gate electrode at a second side of the semiconductor channel, opposite the first side of the semiconductor channel; a gate dielectric layer between the gate electrode and the semiconductor channel; and a hydrogen absorption layer adjacent to the gate electrode, the first source/drain electrode, the second source/drain electrode, or a combination thereof. In some embodiments, the hydrogen absorption layer is embedded in the gate electrode. In some embodiments, the hydrogen absorption layer is in direct contact with the gate dielectric layer. In some embodiments, the hydrogen absorption layer is between the gate electrode and the gate dielectric layer and shares a width with the gate electrode. In some embodiments, the hydrogen absorption layer is between the gate electrode and the gate dielectric layer and further extends along sidewalls of the gate electrode. In some embodiments, the semiconductor device further includes: an additional hydrogen absorption layer; and a plurality of conductive layers alternatingly stacked with the hydrogen absorption layer and the additional hydrogen absorption layer, wherein the plurality of conductive layers form the gate electrode. In some embodiments, the hydrogen absorption layer is between the semiconductor channel and one of the first and second source/drain electrodes and further extends along sidewalls of the one of the first and second source/drain electrodes.

In some embodiments, the present disclosure provides an IC including a semiconductor device, wherein the semiconductor device includes: a semiconductor channel, a gate electrode, and a gate dielectric layer that are stacked with the gate dielectric layer separating the gate electrode from the semiconductor channel; a first source/drain electrode and a second source/drain electrode respectively on different portions of the semiconductor channel; and a hydrogen absorption layer adjacent to the gate electrode and the gate dielectric layer. In some embodiments, the gate electrode includes a conductive body and a barrier layer, which lines sidewalls of the conductive body and a surface of the conductive body facing away from the gate dielectric layer, wherein the hydrogen absorption layer separates the conductive body from the barrier layer. In some embodiments, the IC further includes an interconnect structure overlying a semiconductor substrate and including a plurality of wire levels and a plurality of via levels alternatingly stacked away from the semiconductor substrate, wherein at least one of the plurality of wire levels separates the semiconductor substrate from the semiconductor device. In some embodiments, the semiconductor channel includes a metal-oxide semiconductor material, and wherein the hydrogen absorption layer includes an n-type metal oxide including indium. In some embodiments, the semiconductor channel includes a metal-oxide semiconductor material, and wherein the hydrogen absorption layer includes a noble metal. In some embodiments, the semiconductor channel overlies a semiconductor substrate, wherein the semiconductor channel, the gate electrode, and the gate dielectric layer are vertically stacked with the gate electrode vertically between the gate dielectric layer and the semiconductor substrate. In some embodiments, the semiconductor channel overlies a semiconductor substrate, wherein the semiconductor channel, the gate electrode, and the gate dielectric layer are vertically stacked with semiconductor channel vertically between the gate electrode and the semiconductor substrate.

In some embodiments, the present disclosure provides a method for forming a semiconductor device, including: forming a gate electrode and a hydrogen absorption layer bordering each other; depositing a gate dielectric layer overlying the gate electrode and the hydrogen absorption layer; depositing a semiconductor layer overlying the gate dielectric layer; patterning the semiconductor layer to form a semiconductor channel overlying the gate electrode and the hydrogen absorption layer; and forming a first source/drain electrode and a second source/drain electrode atop the semiconductor channel, laterally spaced from each other. In some embodiments, the method further includes patterning a dielectric layer to form a gate opening, wherein the gate electrode is formed filling the gate opening, and wherein the hydrogen absorption layer is formed overlying the gate electrode and the dielectric layer. In some embodiments, the forming of the gate electrode and the hydrogen absorption layer includes: patterning a dielectric layer to form a gate opening; depositing a barrier layer overlying the dielectric layer and lining the gate opening; depositing the hydrogen absorption layer overlying the barrier layer and lining the gate opening; depositing a conductive layer filling the gate opening over the hydrogen absorption layer; and performing a planarization into the barrier layer, the hydrogen absorption layer, and the conductive layer to expose a top surface of the dielectric layer. In some embodiments, the forming of the gate electrode and the hydrogen absorption layer includes: patterning a dielectric layer to form a gate opening; depositing the hydrogen absorption layer overlying and directly contacting the dielectric layer and further lining the gate opening; depositing a conductive layer filling the gate opening over the hydrogen absorption layer; and performing a planarization into the hydrogen absorption layer and the conductive layer to expose a top surface of the dielectric layer. In some embodiments, the forming of the gate electrode and the hydrogen absorption layer includes: depositing a conductive layer over a dielectric layer; patterning the conductive layer into the gate electrode; and depositing the hydrogen absorption layer over the gate electrode and extending along sidewalls of the gate electrode. In some embodiments, the forming of the gate electrode and the hydrogen absorption layer includes: depositing a film including a plurality of conductive layers, the hydrogen absorption layer, and an additional hydrogen absorption layer, wherein the conductive layers are deposited alternatingly stacked with the hydrogen absorption layer and the additional hydrogen absorption layer; and patterning the film into the gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor channel;
a first source/drain electrode and a second source/drain electrode that are at a first side of the semiconductor channel and that are electrically coupled respectively to different portions of the semiconductor channel;
a gate electrode at a second side of the semiconductor channel, opposite the first side of the semiconductor channel;
a gate dielectric layer between the gate electrode and the semiconductor channel; and
a hydrogen absorption layer adjacent to the gate electrode, the first source/drain electrode, the second source/drain electrode, or a combination thereof.

2. The semiconductor device of claim 1, wherein the hydrogen absorption layer is embedded in the gate electrode.

3. The semiconductor device of claim 1, wherein the hydrogen absorption layer is in direct contact with the gate dielectric layer.

4. The semiconductor device of claim 1, wherein the hydrogen absorption layer is between the gate electrode and the gate dielectric layer and shares a width with the gate electrode.

5. The semiconductor device of claim 1, wherein the hydrogen absorption layer is between the gate electrode and the gate dielectric layer and further extends along sidewalls of the gate electrode.

6. The semiconductor device of claim 1, further comprising:
an additional hydrogen absorption layer; and
a plurality of conductive layers alternatingly stacked with the hydrogen absorption layer and the additional hydrogen absorption layer, wherein the plurality of conductive layers form the gate electrode.

7. The semiconductor device of claim 1, wherein the hydrogen absorption layer is between the semiconductor channel and one of the first and second source/drain electrodes and further extends along sidewalls of the one of the first and second source/drain electrodes.

8. An integrated circuit (IC) comprising a semiconductor device, wherein the semiconductor device comprises:
a semiconductor channel, a gate electrode, and a gate dielectric layer that are stacked with the gate dielectric layer separating the gate electrode from the semiconductor channel;
a first source/drain electrode and a second source/drain electrode respectively on different portions of the semiconductor channel; and
a hydrogen absorption layer adjacent to the gate electrode and the gate dielectric layer.

9. The IC according to claim 8, wherein the gate electrode comprises a conductive body and a barrier layer, which lines sidewalls of the conductive body and a surface of the conductive body facing away from the gate dielectric layer, and wherein the hydrogen absorption layer separates the conductive body from the barrier layer.

10. The IC according to claim 8, further comprising:
an interconnect structure overlying a semiconductor substrate and comprising a plurality of wire levels and a plurality of via levels alternatingly stacked away from the semiconductor substrate, wherein at least one of the plurality of wire levels separates the semiconductor substrate from the semiconductor device.

11. The IC according to claim 8, wherein the semiconductor channel comprises a metal-oxide semiconductor material, and wherein the hydrogen absorption layer comprises an n-type metal oxide comprising indium.

12. The IC according to claim 8, wherein the semiconductor channel comprises a metal-oxide semiconductor material, and wherein the hydrogen absorption layer comprises a noble metal.

13. The IC according to claim 8, wherein the semiconductor channel overlies a semiconductor substrate, and wherein the semiconductor channel, the gate electrode, and the gate dielectric layer are vertically stacked with the gate electrode vertically between the gate dielectric layer and the semiconductor substrate.

14. The IC according to claim 8, wherein the semiconductor channel overlies a semiconductor substrate, and wherein the semiconductor channel, the gate electrode, and the gate dielectric layer are vertically stacked with semiconductor channel vertically between the gate electrode and the semiconductor substrate.

15. A method for forming a semiconductor device, comprising:
forming a gate electrode and a hydrogen absorption layer bordering each other;
depositing a gate dielectric layer overlying the gate electrode and the hydrogen absorption layer;
depositing a semiconductor layer overlying the gate dielectric layer;
patterning the semiconductor layer to form a semiconductor channel overlying the gate electrode and the hydrogen absorption layer; and
forming a first source/drain electrode and a second source/drain electrode atop the semiconductor channel, laterally spaced from each other.

16. The method according to claim 15, further comprising:
patterning a dielectric layer to form a gate opening, wherein the gate electrode is formed filling the gate opening, and wherein the hydrogen absorption layer is formed overlying the gate electrode and the dielectric layer.

17. The method according to claim 15, wherein the forming of the gate electrode and the hydrogen absorption layer comprises:
patterning a dielectric layer to form a gate opening;
depositing a barrier layer overlying the dielectric layer and lining the gate opening;
depositing the hydrogen absorption layer overlying the barrier layer and lining the gate opening;
depositing a conductive layer filling the gate opening over the hydrogen absorption layer; and
performing a planarization into the barrier layer, the hydrogen absorption layer, and the conductive layer to expose a top surface of the dielectric layer.

18. The method according to claim 15, wherein the forming of the gate electrode and the hydrogen absorption layer comprises:
patterning a dielectric layer to form a gate opening;
depositing the hydrogen absorption layer overlying and directly contacting the dielectric layer and further lining the gate opening;
depositing a conductive layer filling the gate opening over the hydrogen absorption layer; and
performing a planarization into the hydrogen absorption layer and the conductive layer to expose a top surface of the dielectric layer.

19. The method according to claim 15, wherein the forming of the gate electrode and the hydrogen absorption layer comprises:
depositing a conductive layer over a dielectric layer;
patterning the conductive layer into the gate electrode; and
depositing the hydrogen absorption layer over the gate electrode and extending along sidewalls of the gate electrode.

20. The method according to claim 15, wherein the forming of the gate electrode and the hydrogen absorption layer comprises:
depositing a film comprising a plurality of conductive layers, the hydrogen absorption layer, and an additional hydrogen absorption layer, wherein the conductive layers are deposited alternatingly stacked with the hydrogen absorption layer and the additional hydrogen absorption layer; and
patterning the film into the gate electrode.
